(19) United States
(12) Patent Application Publication
(10) Pub. No.: US 2018/0130853 A1
(43) Pub. Date: May 10, 2018

(54) DISPLAY COMPONENT AND MANUFACTURING METHOD THEREFOR

(71) Applicant: GUANZHOU CHINARAY OPTOELECTRONIC MATERIALS LTD., Guangzhou (CN)

(72) Inventor: Junyou PAN, Guangzhou (CN)

(21) Appl. No.: 15/535,022

(22) PCT Filed: Dec. 11, 2015
(86) PCT No.: PCT/CN2015/097189

§ 371 Date: Dec. 11, 2017

(30) Foreign Application Priority Data
Dec. 11, 2014 (CN) 201410766326.5

(51) Int. Cl. H01L 27/32; H01L 51/00

(52) U.S. Cl. CPC H01L 27/3211; H01L 51/5056; H01L 51/0004

(57) ABSTRACT

A display device and a preparation method thereof are disclosed, The display device comprises red, green and blue sub-pixels, wherein each sub-pixel is an electroluminescent device and comprises a light-emitting layer, wherein 1) the light-emitting layer of the green sub-pixel contains organic light-emitting material, 2) either or both of the light-emitting layers of the red and blue sub-pixels contain colloidal quantum dot light-emitting material, 3) the light-emitting layer of red, green and blue sub-pixels are all prepared by printing.

### TECHNICAL FIELD

The present disclosure relates to display technology, and more particularly to a composite printed display device comprising QLED and OLED, and a preparation method thereof.

### BACKGROUND

Organic light-emitting diode (OLED) has great potential in the realization of novel optoelectronic devices, such as flat panel display device and is the most promising next generation of display technology, because of diversity in synthesis of organic semiconductors, which enables large area flexible devices, low manufacturing costs and high performance optical and electrical properties.

According to the preparation process, OLED can be divided into evaporation system and soluble system. At present, the more mature is the vapor deposition system, but only for small screen displays, when the screen size increases, it will encounter a very serious metal mask (MASK) problem, thus limiting the cost reduction and yield improvement. This is currently a major factor limiting large-screen OLED displays. Soluble OLED material system can form large area film through digital printing technology, such as inkjet printing technology, without needing MASK, and can greatly reduce the vacuum involved in the production process, thus can greatly reduce costs. Therefore printing OLED is a great potential technology options, is the focus of the current industry research and development direction.

OLED display based on the soluble system of has a variety of technical path. Due to the lack of high-performance soluble blue light material, the most feasible solution is the composite device, in which red and green light emitting layer and hole transport layer (HTL) are print to form a film, and blue light emitting layer and the electron transport layer (ETL) are formed by vapor deposition, but without MASK. The main drawback of the current soluble red material is 1) the luminescence spectrum is too wide, resulting in low color gamut, 2) limited spectrum in the red spectral range power distribution, resulting in low luminous efficiency. There are similar problems with vaporized blue OLEDs. At the same time the current life of printed OLEDs have yet to be improved.

Quantum dot light-emitting diode (QLED) is another new display technology, which has the advantage of narrow luminescence spectrum, high color gamut. But the current green and blue QLED performance is lower, far from commercial.

In addition, it is desirable that the display be fully printed, that is, RGB side-by-side, where the RGB light emitting layer and the hole transport layer (HTL) are printed to form film and the common electron transport layer (ETL) is formed by vapor deposition, without MASK.

Therefore, the existing new printing and display technology has yet to be improved and developed.

### SUMMARY

In view of the above-mentioned deficiencies of the prior art, it is an object of the present disclosure to provide a composite printed display device comprising QLED and OLED, which is intended to solve the existing new display technology problems and to provide a new solution for the printing display.

The technical solution for achieving the above mentioned object is as follows:

A display device comprising red, green and blue sub-pixels, wherein each sub-pixel is an electroluminescent device and comprises a light-emitting layer, characterized in that 1) the light-emitting layer of the green sub-pixel contains organic light-emitting material, 2) either or both of the light-emitting layers of the red and blue sub-pixels contain colloidal quantum dot light-emitting material, 3) the light-emitting layers of the red, green and blue sub-pixels are all prepared by printing.

In some embodiments, the light emitting layer of the green sub-pixel is prepared by ink-jet printing, Nozzle Printing or gravure printing.

In some embodiments, the red, green, and blue sub-pixels each includes a hole injection layer and/or a hole transport layer. In certain preferred embodiments, the red, green, and blue sub-pixels each includes an identical hole injection layer and/or an identical hole transport layer, wherein the hole injection layer and/or the hole transport layer Is prepared by printing, and the printing method may be selected from ink-jet printing, screen printing, gravure printing, spray printing, and slot-die coating.

In some embodiments, the red, green, and blue sub-pixels each includes an identical hole-injecting layer selected from the group consisting of NiOx, WOx, MoOx, RuOx, VOx and any combination thereof, or a conductive polymer.

In some embodiments, either or both of the light-emitting layers of the red and blue sub-pixels contain colloidal quantum dot light-emitting material, wherein the light emitting layer is prepared by ink jet printing, nano imprinting, or gravure printing.

In some embodiments, the red, green, and blue sub-pixels each includes an electron injection layer and/or an electron transport layer.

In some embodiments, the organic light-emitting material is selected from the group consisting of organic small molecules, polymers and organic metal complexes.

In some embodiments, the colloidal quantum dot light-emitting material comprises a semiconductor material selected from the group consisting of CdSe, CdS, CdTe, ZnO, ZnSe, ZnS, ZnTe, HgS, HgSe, HgTe, CdZnSe, InAs, InP, InN, GaN, InSb, InAsP, InGaAs, GaAs, GaP, GaSb, AlP, AlN, AlAs, AlSb, CdSeTe, ZnCdSe, PbSe, PbTe, PbS, PbSnTe, Tl₂SnTe₅, and any combination thereof. Preferably, the colloidal quantum dot light-emitting material has a heterostructure comprising two different semiconductors, wherein the heterostructure is a core/shell structure having at least one shell.

In some embodiments, each sub-pixel comprises at least one thin film transistor (TFT). Preferably, the TFTs may be selected from the group consisting of metal oxide TFTs, organic transistors (OFET), and carbon nanotube transistors (CNT FETs).

It is another object of the present disclosure to further provide a method of preparing each sub-pixel of a display by printing.

Compared with the prior art, the disclosure has the following advantages and technical effects: based on the composite device of the disclosure, the RGB side-by-side printed display is realized by the high performance of the green OLED, the high color gamut of red or blue QLED, and the suitable printing technology. This composite display device can take full advantage of OLED and QLED advantages, and mainly through the printing process to achieve, which is easy to achieve large-size display, and to reduce production costs.

### DETAILED DESCRIPTION OF THE EMBODIMENTS

The present disclosure provides a composite printed display device comprising QLED and OLED and a preparation method thereof. The present disclosure will now be described in greater detail so that the purpose, technical solutions, and technical effects thereof are more clear and comprehensible. It is to be understood that the specific embodiments described herein are merely illustrative of, and are not intended to limit, the disclosure.

The present disclosure provides a display device comprising red, green and blue sub-pixels, wherein each sub-pixel is an electroluminescent device and comprises a light-emitting layer, characterized in that 1) the light-emitting layer of the green sub-pixel contains organic light-emitting material, 2) either or both of the light-emitting layers of the red and blue sub-pixels comprise colloidal quantum dot light-emitting material, 3) the light-emitting layers of the red, green and blue sub-pixels are all prepared by printing.

Electroluminescent devices refer to electronic devices that comprise two ends or three ends, and when a voltage is applied across the ends thereof, the device emits light. Examples of the electroluminescent devices comprising two ends are a ligh emitting diode, a light emitting electrochemical cell. Examples of electroluminescent devices comprising three ends are ligh emitting field-effect transitor (see Nature Materials vol9 496 (2010)), light emitting triode (see Science vol320 570 (2011)). In a preferred embodiment, the electroluminescent device of the present disclosure refers to an electronic device comprising two ends. The voltage can be either DC or AC voltage. In a preferred embodiment, the applied voltage is a DC voltage.

It is to be understood that the red, green and blue triangles of the present disclosure are schematic and have a wide range. And the principles and methods of the present disclosure are generous and are equally suitable for other colors by obvious modifications.

In a preferred embodiment, in the display device according to the present disclosure, a sub-pixel comprises a light emitting diode, i.e., a green sub-pixel comprising an organic light emitting diode (OLED), the red and/or blue sub-pixels comprising a colloidal quantum dot light emitting diode (QLED). Without departing from the generality, the device structure, the materials used and the preparation method described in this preferred embodiment will be described in detail below.

(I) OLED Device Structure

The OLED comprises at least one anode, one cathode, and a light-emitting layer between the two.

The light emitting layer (EML) of the OLED comprises at least one organic light emitting material which may be a singlet emitter (fluorescent light emitter) and a triplet emitter (phosphorescent light emitter). In some particularly preferred embodiments, the light emitting layer of the OLED further comprises a light emitter and a host material, wherein the proportion of the emitter is from 1 wt % to 30 wt %, preferably from 1 wt % to 25 wt %, more preferably from 2 wt % to 20 wt %, most preferably from 3 wt % to 15 wt %.

In some embodiments, a hole injection layer (HIL) is also included between the EML and the anode, which comprises a hole injecting material (HIM).

In some embodiments, a hole transport layer (HTL) or an electron blocking layer (EBL) is included between the EML and the HIL, which includes a hole transport material (HTM) or an electron blocking material (EBM).

In some embodiments, an electron injection layer (EIL) is also included between the EML and the cathode, which comprises an electron injecting material (EIM).

In some embodiments, an electron transport layer (ETL) or a hole blocking layer (HBL) is also included between the EML and EIL, which comprises an electron transport material (ETM) or a hole blocking material (HBM).

In some embodiments, the OLED further comprises an exciton blocking layer (ExBL) located above or below the EML, which contains an organic functional material (ExBM) whose excited state energy level is greater than the excited state energy level of the light emitting material.

The thickness of each functional layer in the OLED is generally in the range of 1 nm to 200 nm, preferably 1 nm to 150 nm, 2 nm to 100 nm, and most preferably 5 nm to 100 nm.

Various variants of OLED device structures are prior art, and are not described here, and please see the references in the prior art,.

(II) QLED Device Structure

QLED comprises at least one anode, one cathode, and a light-emitting layer between the two.

The light emitting layer (EML) of the QLED comprises at least one colloidal quantum dot light emitting material. In some embodiments, the light emitting layer of QLED further comprises a host material. In a preferred embodiment, the light emitting layer (EML) of the QLED comprises only the quantum dot light emitting material.

In some embodiments, a hole injection layer (HIL) is also included between the EML and the anode, which comprises a hole injecting material (HIM).

In some embodiments, a hole transport layer (HTL) or an electron blocking layer (EBL) is included between the EML and the HIL, which comprises a hole transport material (HTM) or an electron blocking material (EBM).

In some embodiments, an electron injection layer (EIL) is also included between the EML and the cathode, which comprises an electron injecting material (EIM).

In some embodiments, an electron transport layer (ETL) or a hole blocking layer (HBL) is also included between the EML and EIL, which comprises an electron transport material (ETM) or a hole blocking material (HBM).

In some embodiments, the QLED also contains an electron blocking layer (EBL) located between the EML and the cathode (see Nature vol 515 96 (2014)).

The thickness of each functional layer in QLED is generally in the range of 1 nm to 200 nm, preferably 1 nm to 150 nm, 2 nm to 100 nm, and most preferably 5 nm to 100 nm.

Various variants of QLED device structures are prior art, see the references in the prior art, and are not described here.

The present disclosure relates to various functional materials including light emitters, HIM, HTM, EBM, host materials, HBM, ETM, EIM. Various functional materials will be described in detail in the following.

The organic functional material may be small molecules or polymer materials.

As used herein, the term “small molecules” refers to a molecule that is not a polymer, an oligomer, a dendrimer, or a blend. In particular, there is no repetitive structure in small molecules. The molecular weight of the small molecule is no greater than 3000 g/mole, more preferably no greater than 2000 g/mole, and most preferably no greater than 1500 g/mole.

“Polymer” includes homopolymer, copolymer, and block copolymer. In addition, in the present disclosure, the polymer also includes dendrimer. The synthesis and application of dendrimers are described in Dendrimers and Dendrons, Wiley-VCH Verlag GmbH & Co. KGaA, 2002, Ed. George R. Newkome , Charles N. Moorefield, Fritz Vogtle.

“Conjugated polymer” is a polymer whose backbone is predominantly composed of the sp² hybrid orbital of carbon (C) atom. Some known examples are: polyacetylene and poly (phenylene vinylene), on the backbone of which the C atom can also be optionally substituted by other non-C atoms, and which is still considered to be a conjugated polymer when the sp² hybridization on the backbone is interrupted by some natural defects. In addition, the conjugated polymer in the present disclosure may also comprise aryl amine, aryl phosphine and other heteroarmotics, organic metal complexes, and the like.

In the embodiments of the present disclosure, the host material, the matrix material, Host material and Matrix material have the same meaning and are interchangeable.

These organic functional materials are described in detail, for example, in WO2010135519A1, US20090134784A1 and WO 2011110277A1, the entire contents of which are incorporated herein by reference.

The organic functional material is described in detail in the following (but not limited thereto).

1. HIM/HTM/EBM

Suitable organic HIM/HTM materials may include any one of the compounds having the following structural units: phthalocyanines, porphyrins, amines, aromatic amines, biphenyl triaromatic amines, thiophenes, thiophenes such as dithiophenethiophene and thiophthene, pyrrole, aniline, carbazole, indeno-fluorene, and derivatives thereof. Other suitable HIMs also include: fluorocarbon-containing polymers; polymers containing conductive dopants; conductive polymers such as PEDOT/PSS; self-assembled monomers such as compounds containing phosphonic acid and sliane derivatives; metal oxides, such as MoOx; metal complex, and a crosslinking compound, and the like.

The electron blocking layer (EBL) is typically used to block electrons from adjacent functional layers, particularly light emitting layers. In contrast to a light-emitting device without a blocking layer, the presence of EBL usually results in an increase in luminous efficiency. The electron blocking material (EBM) of the electron blocking layer (EBL) requires a higher LUMO than that of the adjacent functional layer, such as the light emitting layer. In a preferred embodiment, the EBM has a greater energy level of excited state than that of the adjacent light emitting layer, such as a singlet or triplet level, depending on the emitter. In another preferred embodiment, the EBM has a hole transport function. HIM/HTM materials, which typically have high LUMO levels, can be used as EBM.

Other examples of cyclic aromatic amine derivative compounds that may be used as HIM/HTM/EBM may include, but are not limited to, the general structure as follows:

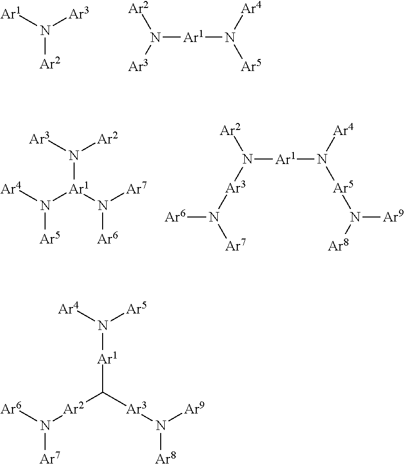

wherein each Ar¹ to Ar⁹ may be independently selected from the group consisting of: cyclic aromatic hydrocarbon compounds such as benzene, biphenyl, triphenyl, benzo, naphthalene, anthracene, phenalene, phenanthrene, fluorene, pyrene, chrysene, perylene, azulene; and aromatic heterocyclic compounds such as dibenzothiophene, dibenzofuran, furan, thiophene, benzofuran, benzothiophene, carbazole, pyrazole, imidazole, triazole, isoxazole, thiazole, oxadiazole, oxatriazole, dioxazole, thiadiazole, pyridine, pyridazine, pyrimidine, pyrazine, triazine, oxazine, oxathiazin, oxadiazine, indole, benzimidazole, indazole, indoxazine, bisbenzoxazole, benzisoxazole, benzothiazole, quinoline, isoquinoline, o-diazo (m) naphthalene, quinazoline, quinoxaline, naphthalene, phthalein, pteridine, xanthene, acridine, phenazine, phenothiazine, phenoxazine, dibenzoselenophene, benzoselenophene, benzofuropyridine, indolocarbazole, pyridylindole, pyrrolodipyridine, furodipyridine, benzothienopyridine, thienodipyridine, benzoselenophenopyridine, and selenophenodipyridine; groups containing 2 to 10 membered ring structures which may be the same or different types of aromatic cyclic or aromatic heterocyclic groups and are bonded to each other directly or through at least one of the following groups, for example: oxygen atom, nitrogen atom, sulfur atom, silicon atom, phosphorus atom, boron atom, chain structure unit, and aliphatic cyclic group; and wherein each Ar may be further optionally substituted, and the substituents may optionally be hydrogen, alkyl, alkoxy, amino, alkene, alkyne, aralkyl, heteroalkyl, aryl and heteroaryl.

In one aspect, Ar¹ to Ar⁹ may be independently selected from the groups of the group consisting of:

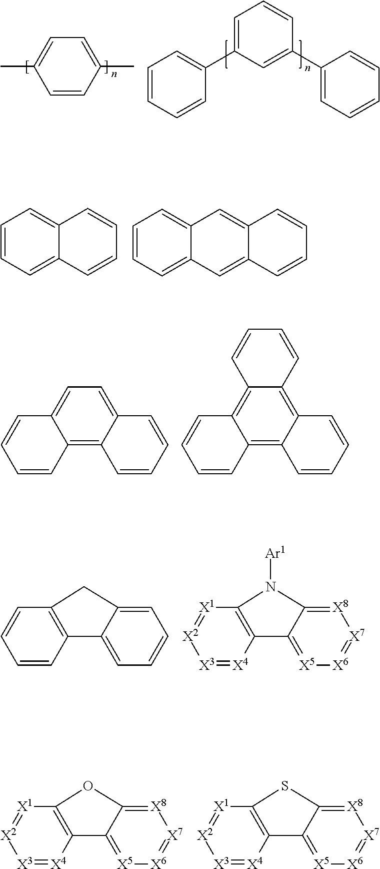

wherein n is an integer of 1 to 20; X¹ to X⁸ are CH or N; Ar¹ is as defined above.

Additional examples of cyclic aromatic amine derivative compounds may be found in U.S. Pat. No. 3,567,450, U.S. Pat. No. 4,720,432, U.S. Pat. No. 5,061,569, U.S. Pat. No. 3,615,404, and U.S. Pat. No. 5,061,569.

Examples of metal complexes that can be used as HTM or HIM include, but not limited to, the following general structures:

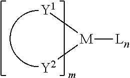

M is a metal, having an atomic weight greater than 40;

(Y¹—Y²) is a bidentate ligand, wherein Y¹ and Y² are independently selected from the group consisting of C, N, O, P, and S; L is an auxiliary ligand; m is an integer from 1 to the maximum coordination number of the metal; m+n is the maximum coordination number of the metal.

In one embodiment, (Y¹—Y²) may be a 2-phenylpyridine derivative.

In another embodiment, (Y¹—Y²) may be a carbene ligand.

In another embodiment, M may be selected from the group consisting of Ir, Pt, Os, and Zn.

In another aspect, the HOMO of the metal complex is greater than −5.5 eV (relative to the vacuum level).

Examples of a suitable HIM/HTM/EBM compound are listed below:

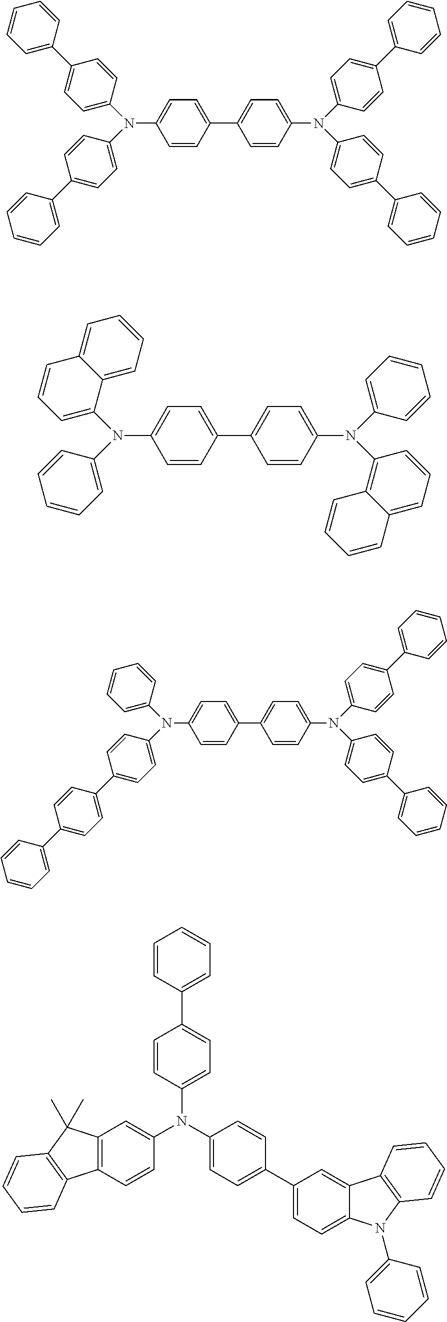 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4cccc5ccccc45)cc3)cc2)c2cccc3ccccc23)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

Inorganic p-type semiconductor materials can also be used as HIM or HTM. Preferred inorganic p-type semiconductor materials are selected from the group consisting of NiOx, Wox, MoOx, RuOx, VOx, and any combination thereof. The HIL or HTL layer based on the inorganic material can be prepared by various methods. In one embodiment, the sol-gel method using the precursor is used. The sol-gel method of NiOx film can be found in Acta Chim. Slov. 2006, 53, p136, and Sol-Gel MoOx film can be found in Sensors & Actuators B 2003, 93, p25. In a preferred embodiment, HIL or HTL comprising the inorganic material can be prepared by co-firing the nanometer crystal at low temperature. In another preferred embodiment, the inorganic material HIL or HTL layer may be prepared by physical vapor deposition, such as by RF magnetron sputtering, as reported by Tokito et al. (J. Phys. D: Appl. Phys. 1996, 29, p2750). Other suitable physical vapor deposition methods can be found in the Physical Vapor Deposition (PVD) manual, Donald M. Mattox, ISBN 0-8155-1422-0, Noyes Publications.

2. EIM/ETM/HBM

Examples of EIM/ETM material are not particularly limited, and any metal complex or organic compound may be used as EIM/ETM as long as they can transfer electrons. Preferred organic EIM/ETM materials may be selected from the group consisting of tris (8-quinolinolato) aluminum (AlQ3), phenazine, phenanthroline, anthracene, phenanthrene, fluorene, bifluorene, spiro-bifluorene, p-phenylene-vinylene, triazine, triazole, imidazole, pyrene, perylene, trans-indenofluorene, cis-indenonfluorene, dibenzol-indenofluorene, indenonaphthalene, benzanthracene and their derivatives.

The hole-blocking layer (HBL) is typically used to block holes from adjacent functional layers, particularly light-emitting layers. In contrast to a light-emitting device without a blocking layer, the presence of HBL usually leads to an increase in luminous efficiency. The hole-blocking material (HBM) of the hole-blocking layer (HBL) requires a lower HOMO than that of the adjacent functional layer, such as the light-emitting layer. In a preferred embodiment, the HBM has a greater energy level of excited state than that of the adjacent light-emitting layer, such as a singlet or triplet, depending on the emitter. In another preferred embodiment, the HBM has an electron-transport function. Typically, EIM/ETM materials with deep HOMO levels may be used as HBM.

In another aspect, compounds that may be used as EIM/ETM/HBM compounds may be molecules comprising at least one of the following groups:

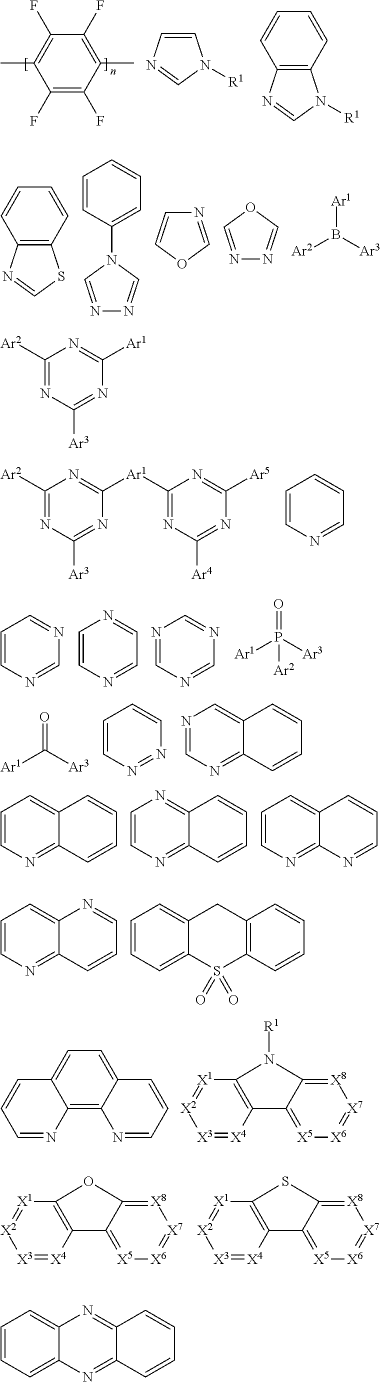

wherein R¹ may be selected from the group consisting of: hydrogen, alkyl, alkoxy, amino, alkene, alkyne, aralkyl, heteroalkyl, aryl and heteroaryl, wherein, when they are aryl or heteroaryl , they may have the same meaning as Ar¹ and Ar² in HTM as described above;

Ar¹- Ar⁵ may have the same meaning as Ar' in HTM as described above;

n is an integer from 0 to 20; and X¹ - X⁸ may be selected from CR¹ or N.

On the other hand, examples of metal complexes that may be used as EIM/ETM may include, but are not limited to, the following general structure:

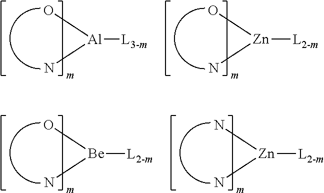

(O—N) or (N—N) is a bidentate ligand, wherein the metal coordinates with O, N, or N, N; L is an auxiliary ligand; and m is an integer whose value is from 1 to the maximum coordination number of the metal.

An example of a suitable ETM compound is listed below:

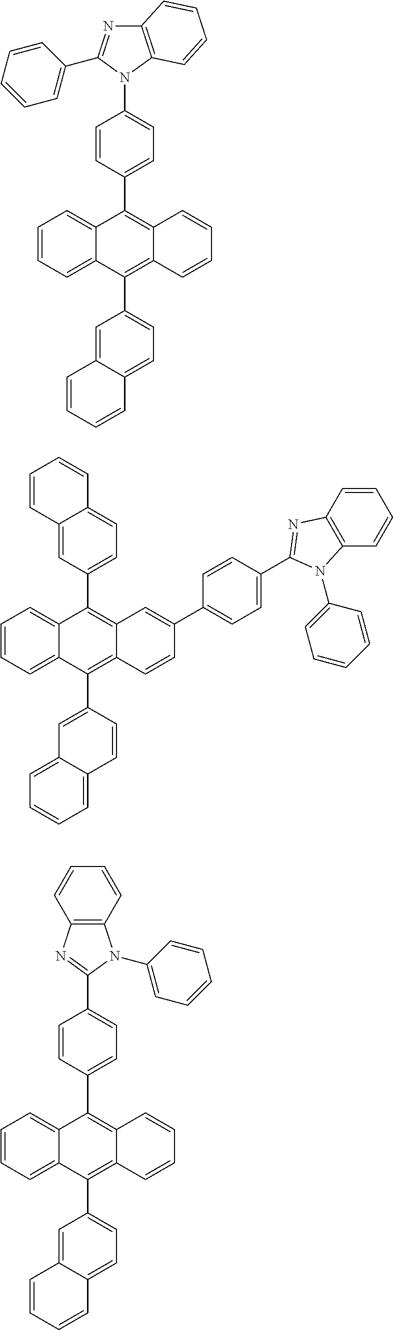

In another preferred embodiment, the organic alkali metal compound may be used as the EIM. In the present disclosure, the organic alkali metal compound may be understood as a compound having at least one alkali metal, i.e., lithium, sodium, potassium, rubidium, and cesium, and further comprising at least one organic ligand. Suitable organic alkali metal compounds include the compounds described in U.S. Pat. No. 7,767,317B2, EP 1941562B1 and EP 1144543B1.

The preferred organic alkali metal compound may be a compound of the following formula:

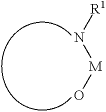

wherein R¹ has the same meaning as described above, and the arc represents two or three atoms and the bond to form a 5- or 6-membered ring with metal M when necessary, while the atoms may be optionally substituted by one or more R¹; and wherein M is an alkali metal selected from the group consisting of lithium, sodium, potassium, rubidium, and cesium.

The organic alkali metal compound may be in the form of a monomer, as described above, or in the form of an aggregate, for example, two alkali metal ions with two ligands, four alkali metal ions and four ligands, six alkali metal ions and six ligands, or in other forms.

The preferred organic alkali metal compound may be a compound of the following formula:

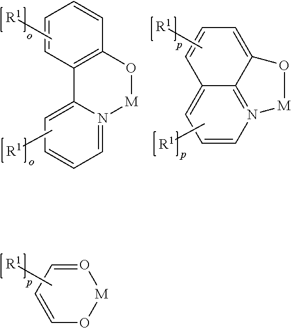

wherein the symbols used are as defined above, and in addition:

o, it may be the same or different in each occurrence, selected from 0, 1, 2, 3 or 4; and

p, it may be the same or different in each occurrence, selected from 0, 1, 2 or 3.

In a preferred embodiment, the alkali metal M is selected from the group consisting of lithium, sodium, potassium, more preferably lithium or sodium, and most preferably lithium.

In a preferred embodiment, the electron-injection layer includes the organic alkali metal compound, and more preferably the electron-injection layer consists of the organic alkali metal compound.

In another preferred embodiment, the organic alkali metal compound is doped into other ETMs to form an electron-transport layer or an electron-injection layer, more preferably an electron-transport layer.

Examples of a suitable organic alkali metal compound are listed below:

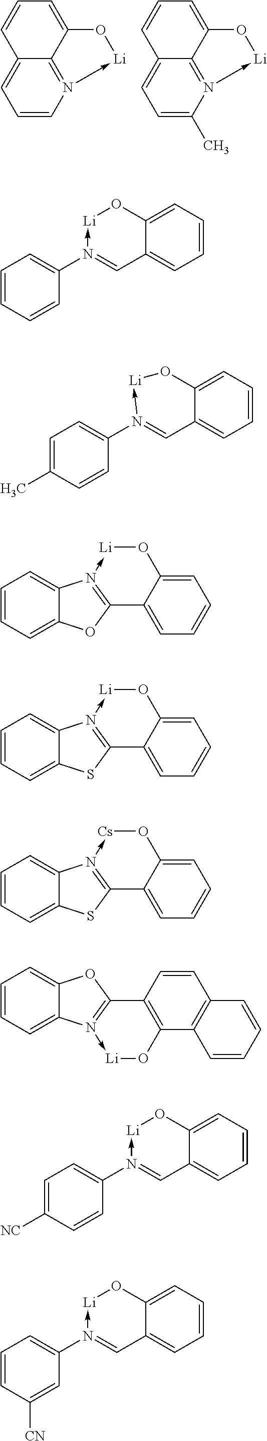

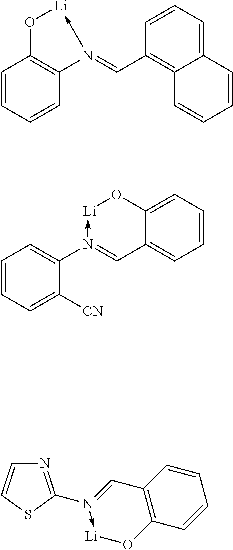

Inorganic n-type semiconductor materials can also be used as EIM or ETM. Examples of inorganic n-type semiconductor materials include, but are not limited to, metallic chalcogenides, metal pnictide, or elemental semiconductors such as metal oxides, metal sulfides, metal selenides, metal tellurides, metal nitrides, metal phosphide, or metal arsenide. Preferred inorganic n-type semiconductor materials are selected from the group consisting of ZnO, ZnS, ZnSe, TiO₂, ZnTe, GaN, GaP, AlN, CdSe, CdS, CdTe, CdZnSe and any combination thereof. The EIL or ETL based on the inorganic material can be prepared by various methods. In one embodiment, the sol-gel method using the precursor is used. The sol-gel method of ZnO film can be found in Chem. Mater. 2009, 21, p604, and the sol-gel method using the precursor of the ZnS film can be found in Nat. Mater. 2011, 10, p45. In a preferred embodiment, EIL or ETL comprising the inorganic material can be prepared by co-firing the nanometer crystal at low temperature. In another preferred embodiment, the inorganic material EIL or ETL layer may be prepared by physical vapor deposition, such as by RF magnetron sputtering.

For QLED, the preferred EIM or ETM is an inorganic n-type semiconductor material, in particular ZnO, ZnS, ZnSe, TiO₂.

3. Triplet Host Materials

Examples of a triplet host material are not particularly limited and any metal complex or organic compound may be used as the host material as long as its triplet energy is greater than that of the emitter, especially a triplet emitter or phosphorescent emitter.

Examples of metal complexes that may be used as triplet hosts may include, but are not limited to, the general structure as follows:

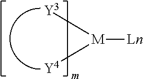

wherein M is a metal; (Y³—Y⁴) may be a bidentate ligand, Y³ and Y⁴ may be independently selected from the group consisting of C, N, O, P, and S; L is an auxiliary ligand; m is an integer with the value from 1 to the maximum coordination number of the metal; and, m+n is the maximum number of coordination of the metal.

In a preferred embodiment, the metal complex which may be used as the triplet host has the following form:

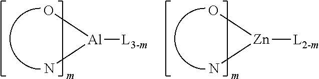

(O—N) is a bidentate ligand in which the metal is coordinated to 0 and N atoms.

In one embodiment, M may be selected from Ir and Pt.

Examples of organic compounds that may be used as triplet host are selected from the group consisting of: compounds containing cyclic aromatic hydrocarbon groups, such as benzene, biphenyl, triphenyl, benzo, and fluorene; compounds containing aromatic heterocyclic groups, such as dibenzothiophene, dibenzofuran, dibenzoselenophen, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazin, oxadiazine, indole, benzimidazole, indazole, indoxazine, bisbenzoxazole, benzothiazole, benzothiazole, quinoline, isoquinoline, cinnoline, quinazoline, quinoxaline, naphthalene, phthalein, pteridine, oxanthene, acridine, phenazine, phenothiazine, phenoxazine, benzofuropyridine, furodipyridine, benzothienopyridine, thienodipyridine, benzoselenophenopyridine, and selenophenodipyridine; groups containing 2 to 10 membered ring structures which may be the same or different types of aromatic cyclic or aromatic heterocyclic groups and are bonded to each other directly or through at least one of the following groups, for example: oxygen atom, nitrogen atom, sulfur atom, silicon atom, phosphorus atom, boron atom, chain structure unit, and aliphatic cyclic group; and wherein each Ar may be further optionally substituted, and the substituents may optionally be hydrogen, alkyl, alkoxy, amino, alkene, alkyne, aralkyl, heteroalkyl, aryl and heteroaryl.

In a preferred embodiment, the triplet host material may be selected from compounds comprising at least one of the following groups:

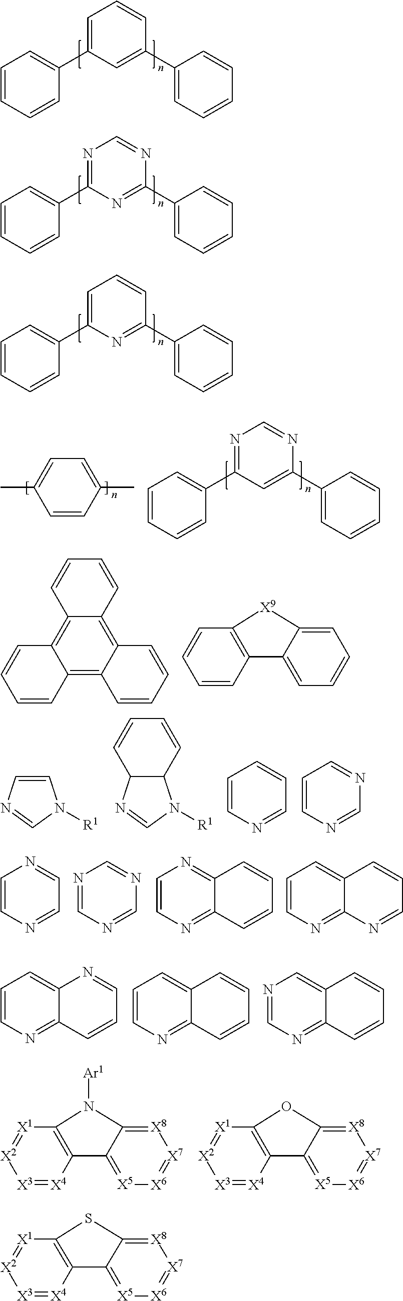

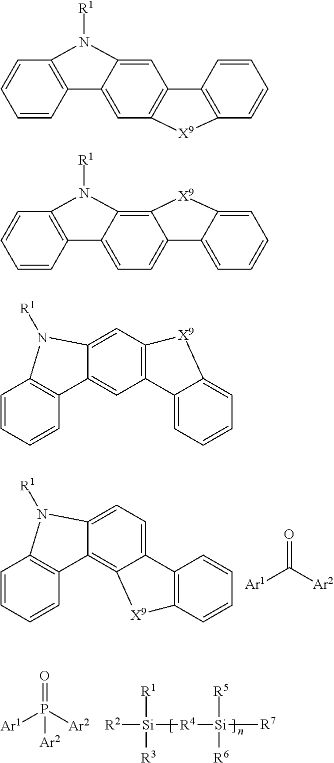

R¹-R⁷ may be independently selected from the group consisting of hydrogen, alkyl, alkoxy, amino, alkene, alkyne, aralkyl, heteroalkyl, aryl and heteroaryl, which may have the same meaning as Ar¹ and Ar² described above when they are aryl or heteroaryl; n may be an integer from 0 to 20; X¹- X⁸ may be selected from CH or N; and X⁹ may be selected from CR¹R2 or NR1.

Examples of suitable triplet host material are listed below:

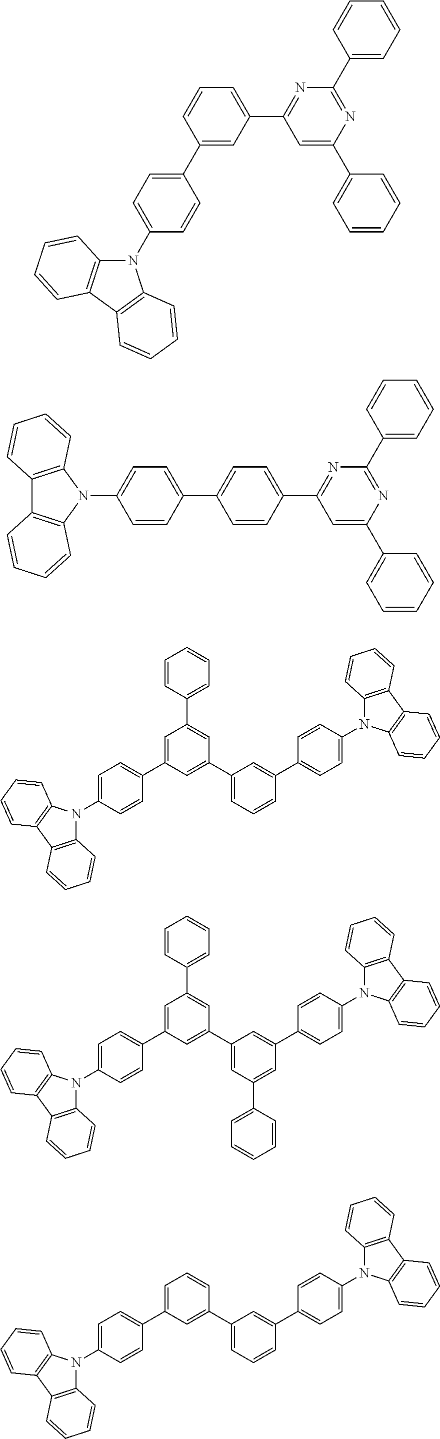 [SMILES: c1ccc(-c2cc(-c3cccc(-c4ccc(-n5c6ccccc6c6ccccc65)cc4)c3)nc(-c3ccccc3)n2)cc1 ; c1ccc(-c2cc(-c3ccc(-c4ccc(-n5c6ccccc6c6ccccc65)cc4)cc3)nc(-c3ccccc3)n2)cc1 ; c1ccc(-c2cc(-c3ccc(-n4c5ccccc5c5ccccc54)cc3)cc(-c3cccc(-c4ccc(-n5c6ccccc6c6ccccc65)cc4)c3)c2)cc1 ; c1ccc(-c2cc(-c3ccc(-n4c5ccccc5c5ccccc54)cc3)cc(-c3cc(-c4ccccc4)cc(-c4ccc(-n5c6ccccc6c6ccccc65)cc4)c3)c2)cc1 ; c1cc(-c2ccc(-n3c4ccccc4c4ccccc43)cc2)cc(-c2cccc(-c3ccc(-n4c5ccccc5c5ccccc54)cc3)c2)c1]

4. Singlet Host Material:

Examples of singlet host material are not particularly limited and any organic compound may be used as the host as long as its singlet state energy is greater than that of the emitter, especially the singlet emitter or fluorescent emitter.

Examples of organic compounds used as singlet host materials may be selected from the group consisting of: compounds containing cyclic aromatic hydrocarbon groups, such as benzene, biphenyl, triphenyl, benzo, naphthalene, anthracene, phenalene, phenanthrene, fluorene, pyrene, chrysene, perylene, azulene; aromatic heterocyclic compounds, such as dibenzothiophene, dibenzofuran, dibenzoselenophen, furan, thiophene, benzofuran, benzothiophene, benzoselenophene, carbazole, indolocarbazole, pyridylindole, pyrrolodipyridine, pyrazole, imidazole, triazole, isoxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzothoxazole, benzothiazole, quinoline, isoquinoline, cinnoline, quinazoline, quinoxaline, naphthalene, phthalide, pteridine, oxacanthracene, acridine, phenazine, phenothiazine, phen oxazine, benzofuropyridine, furodipyridine, benzothienopyridine, thienodipyridine, benzoselenophenopyridine and selenophenodipyridine; and groups comprising 2 to 10 membered ring structures, which may be the same or different types of aromatic cyclic or aromatic heterocyclic groups and are linked to each other directly or by at least one of the following groups, such as oxygen atom, nitrogen atom, sulfur atom, silicon atom, phosphorus atom, boron atom, chain structure unit, and aliphatic rings.

In a preferred embodiment, the singlet host material may be selected from compounds comprising at least one of the following groups:

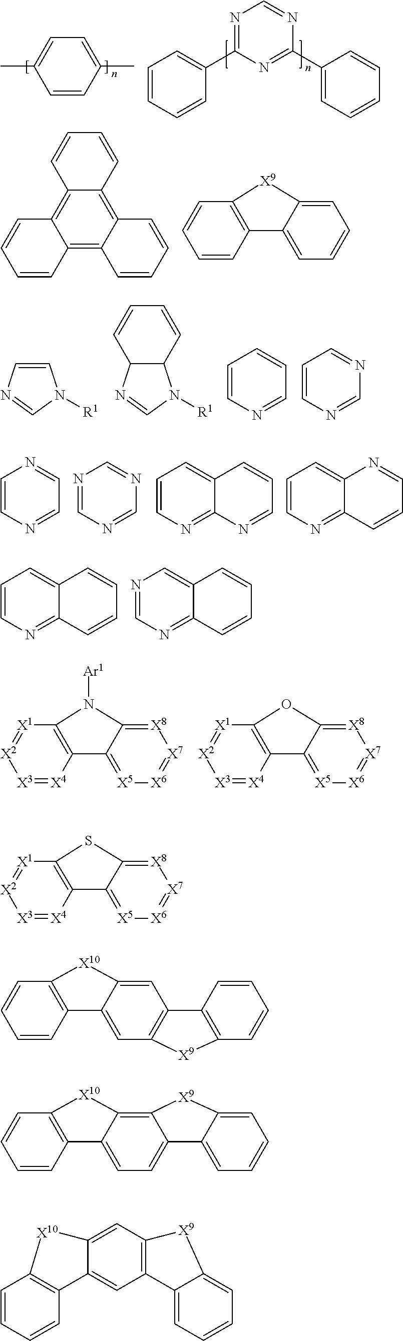

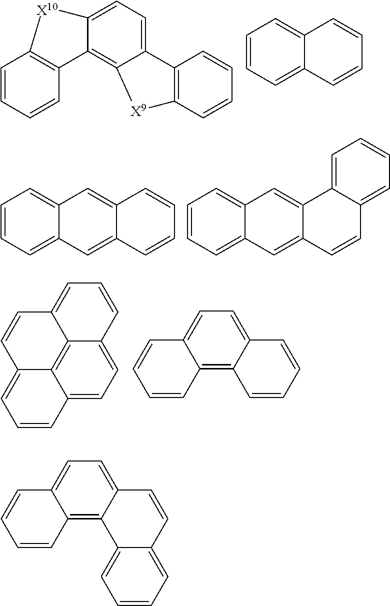

R¹ may be independently selected from the group consisting of hydrogen, alkyl, alkoxy, amino, alkene, alkyne, aralkyl, heteroalkyl, aryl and heteroaryl; Ar¹ is aryl or heteroaryl and has the same meaning as Ar¹ defined in the HTM above; n is an integer from 0 to 20; X¹- X⁸ is selected from CH or N; X⁹ and X¹⁰ are selected from CR¹R² or NR¹.

Examples of a suitable singlet host material are listed below:

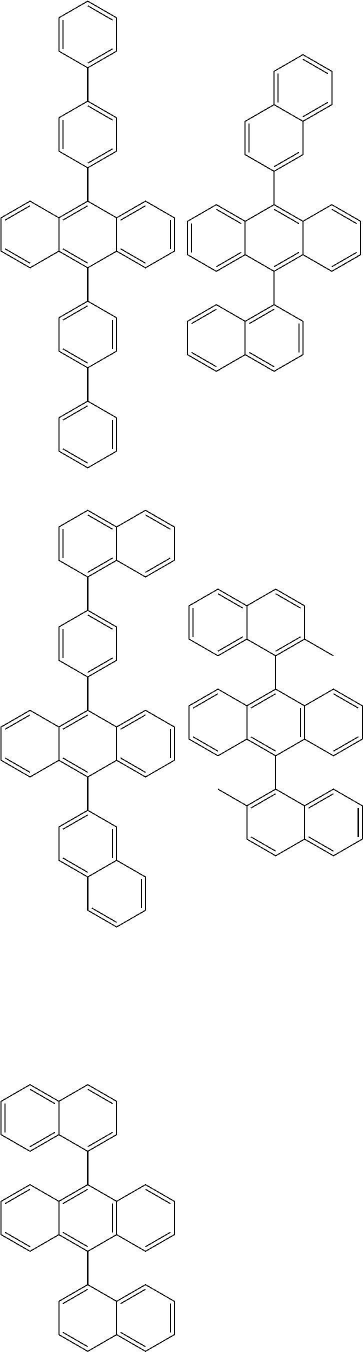

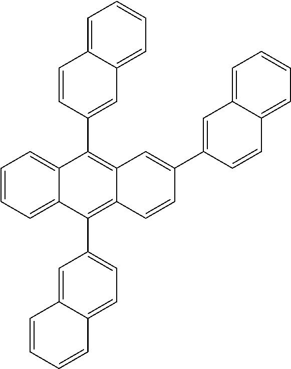 [SMILES: c1ccc2cc(-c3ccc4c(-c5ccc6ccccc6c5)c5ccccc5c(-c5ccc6ccccc6c5)c4c3)ccc2c1]

4. Singlet Emitter

The singlet emitter tends to have a longer conjugate π-electron system. To date, there have been many examples, such as, but not limited to, styrylamine and derivatives thereof disclosed in JP2913116B and WO2001021729A1, and indenofluorene and derivatives thereof disclosed in WO2008/006449 and WO2007/140847.

In a preferred embodiment, the singlet emitter may be selected from the group consisting of monostyrylamines, distyrylamines, tristyrylamines, tetrastyrylamines, styrylphosphines, styryl ethers, and arylamines.

Mono styrylamine refers to a compound which comprises an unsubstituted or optionally substituted styryl group and at least one amine, most preferably an aromatic amine. Distyrylamine refers to a compound comprising two unsubstituted or optionally substituted styryl groups and at least one amine, most preferably an aromatic amine. Ternarystyrylamine refers to a compound which comprises three unsubstituted or optionally substituted styryl groups and at least one amine, most preferably an aromatic amine. Quaternarystyrylamine refers to a compound comprising four unsubstituted or optionally substituted styryl groups and at least one amine, most preferably an aromatic amine. Preferred styrene is stilbene, which may be further optionally substituted. The corresponding phosphines and ethers are defined similarly to amines. Aryl amine or aromatic amine refers to a compound comprising three unsubstituted or optionally substituted aromatic cyclic or heterocyclic systems directly attached to nitrogen. At least one of these aromatic cyclic or heterocyclic systems is preferably selected from fused ring systems and most preferably has at least 14 aromatic ring atoms. Among the preferred examples are aromatic anthramine, aromatic anthradiamine, aromatic pyrene amines, aromatic pyrene diamines, aromatic chrysene amines and aromatic chrysene diamine. Aromatic anthramine refers to a compound in which a diarylamino group is directly attached to anthracene, most preferably at position 9. Aromatic anthradiamine refers to a compound in which two diarylamino groups are directly attached to anthracene, most preferably at positions 9, 10. Aromatic pyrene amines, aromatic pyrene diamines, aromatic chrysene amines and aromatic chrysene diamine are similarly defined, wherein the diarylarylamino group is most preferably attached to position 1 or 1 and 6 of pyrene.

Examples of singlet emitter based on vinylamine and arylamine are also preferred examples which may be found in the following patent documents: WO 2006/000388, WO 2006/058737, WO 2006/000389, WO 2007/065549 , WO 2007/115610, U.S. Pat. No. 7,250,532 B2, DE 102005058557 A1, CN 1583691 A, JP 08053397 A, U.S. Pat. No. 6,251,531 B1, US 2006/210830 A, EP 1957606 A1, and US 2008/0113101 A1, the whole contents of which are incorporated herein by reference.

Examples of singlet light emitters based on distyrylbenzene and its derivatives may be found in, for example, U.S. Pat. No. 5,121,029.

Further preferred singlet emitters may be selected from the group consisting of: indenofluorene-amine and indenofluorene-diamine such as disclosed in WO 2006/122630, benzoindenofluorene-amine and benzoindenofluorene-diamine such as disclosed in WO 2008/006449, dibenzoindenofluorene-amine and dibenzoindenofluorene-diamine such as disclosed in WO2007/140847.

Other materials useful as singlet emitters include, but not limited to, polycyclic aromatic compounds, especially any one selected from the derivatives of the following compounds: anthracenes such as 9,10-di-naphthylanthracene, naphthalene, tetraphenyl, oxyanthene, phenanthrene, perylene such as 2,5,8,11-tetra-t-butylatedylene, indenoperylene, phenylenes such as 4,4′-(bis(9-ethyl-3-carbazovinylene)-1,1′-biphenyl, periflanthene, decacyclene, coronene, fluorene, spirobifluorene, arylpyren (e.g., US20060222886), arylenevinylene (e.g., U.S. Pat. No. 5,121,029, U.S. Pat. No. 5,130,603), cyclopentadiene such as tetraphenylcyclopentadiene, rubrene, coumarine, rhodamine, quinacridone, pyrane such as 4 (dicyanoethylene)-6-(4-dimethylaminostyryl-2-methyl)-4H-pyrane (DCM), thiapyran, bis(azinyl)imine-boron compounds (US 2007/0092753 A1), bis(azinyl)methene compounds, carbostyryl compounds, oxazone, benzoxazole, benzothiazole, benzimidazole, and diketopyrrolopyrrole. Examples of some singlet emitter materials may be found in the following patent documents: US 20070252517 A1, U.S. Pat. No. 4,769,292, U.S. Pat. No. 6,020,078, US 2007/0252517 A1, US 2007/0252517 A1, the whole contents of which are incorporated herein by reference.

Examples of suitable singlet emitters are listed below:

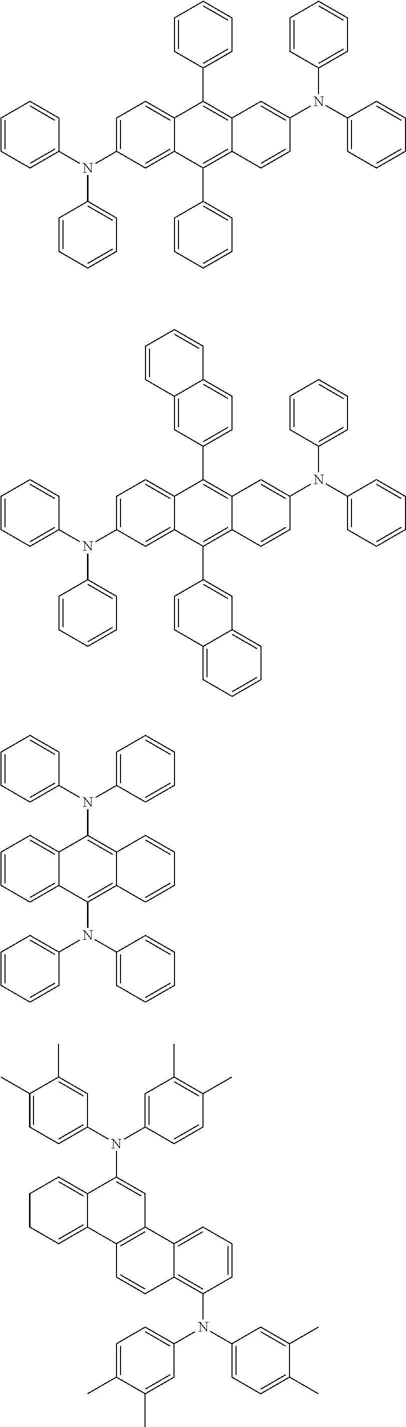

5. Triplet Emitter

The triplet emitter is also called a phosphorescent emitter. In a preferred embodiment, the triplet emitter may be a metal complex of the general formula M (L) n, wherein M is a metal atom; L is the same or different organic ligand in each occurrence, and may be bonded or coordinated to the metal atom M at one or more positions; n is an integer greater than 1, preferably 1, 2, 3, 4, 5 or 6. Alternatively, these metal complexes may be attached to a polymer by one or more positions, most preferably through an organic ligand.

In a preferred embodiment, the metal atom M is selected from the group consisting of transition metal elements, lanthanides and actinides, preferably Ir, Pt, Pd, Au, Rh, Ru, Os, Sm, Eu, Gd, Tb, Dy, Re, Cuor Ag, and particularly preferably Os, Ir, Ru, Rh, Re, Pd, or Pt.

Preferably, the triplet emitter comprises a chelating ligand, i.e., a ligand, coordinated to the metal by at least two bonding sites, and it is particularly preferred that the triplet emitter comprises two or three identical or different bidentate or multidentate ligand. Chelating ligands help to improve stability of metal complexes.

Non-limiting examples of organic ligands may be selected from the group consisting of phenylpyridine derivatives, 7,8-benzoquinoline derivatives, 2 (2 -thienyl) pyridine derivatives, 2 (1-naphthyl) pyridine derivatives, or 2 phenylquinoline derivatives. All of these organic ligands may be optionally substituted, for example, optionally substituted with fluoromethyl or trifluoromethyl. The auxiliary ligand may be preferably selected from acetylacetonate or picric acid.

In a preferred embodiment, the metal complex which may be used as the triplet emitter may have the following form:

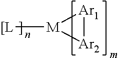

wherein M is a metal selected from the group consisting of transition metal elements, lanthanides and actinides;

Ar¹ may be the same or different cyclic group in each occurrence, which comprises at least one donor atom, that is, an atom with a lone pair of electrons, such as nitrogen atom or phosphorus atom, which is coordinated to the metal through its ring group; Ar² may be the same or different cyclic group in each occurrence, which comprises at least one C atom and is coordinated to the metal through its ring group; A¹ and Ar² are covalently bonded together, wherein each of them carries one or more substituents which may also be joined together by substituents; L may be the same or different at each occurrence and is an auxiliary ligand, preferably a bidentate chelating ligand, and most preferably a monoanionic bidentate chelating ligand; m is 1, 2 or 3, preferably 2 or 3, and particularly preferably 3; and, N is 0, 1, or 2, preferably 0 or 1, particularly preferably 0.

Examples of triplet emitter materials and their applications may be found in the following patent documents and references: WO 200070655, WO 200141512, WO 200202714, WO 200215645, EP 1191613, EP 1191612, EP 1191614, WO 2005033244, WO 2005019373, US 2005/0258742, WO 2009146770, WO 2010015307, WO 2010031485, WO 2010054731, WO 2010054728, WO 2010086089, WO 2010099852, WO 2010102709, US 20070087219 A1, US 20090061681 A1, US 20010053462 A1, Baldo, Thompson et al. Nature 403, (2000), 750-753, US 20090061681 A1, US 20090061681 A1, Adachi et al. Appl. Phys. Lett. 78 (2001), 1622-1624, J. Kido et al. Appl. Phys. Lett. 65 (1994), 2124, Kido et al. Chem. Lett. 657, 1990, US 2007/0252517 A1, Johnson et al., JACS 105, 1983, 1795, Wrighton, JACS 96, 1974, 998, Ma et al., Synth. Metals 94, 1998, 245, U.S. Pat. No. 6,824,895, U.S. Pat. No. 7,029,766, U.S. Pat. No. 6,835,469, U.S. Pat. No. 6,830,828, US 20010053462 A1, WO 2007095118 A1, US 2012004407A1, WO 2012007088A1, WO2012007087A1, WO 2012007086A1, US 2008027220A1, WO 2011157339A1, CN 102282150A and WO 2009118087A1, the entire contents of which are incorporated herein by reference.

Non-limiting examples of suitable triplet emitter are given in the following table:

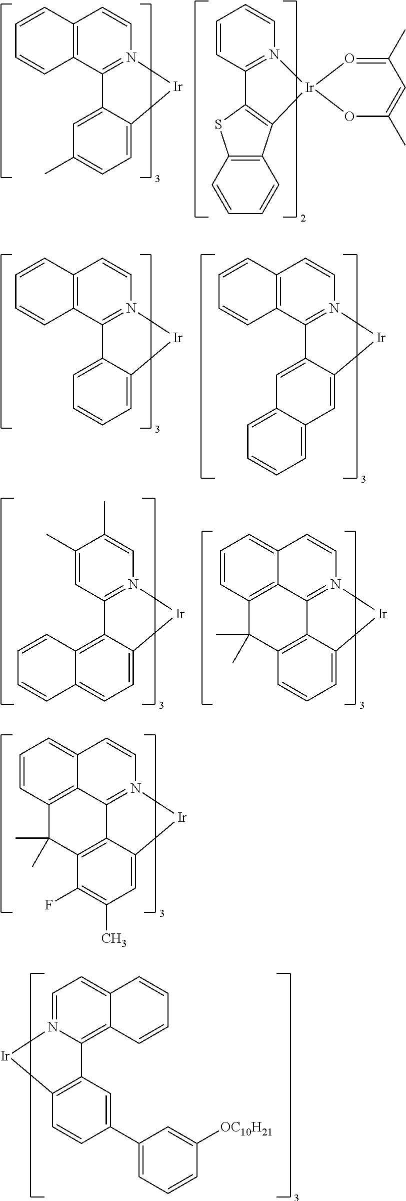

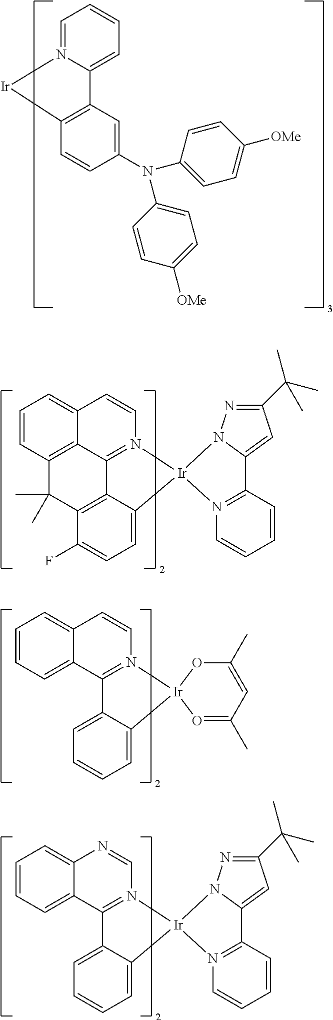

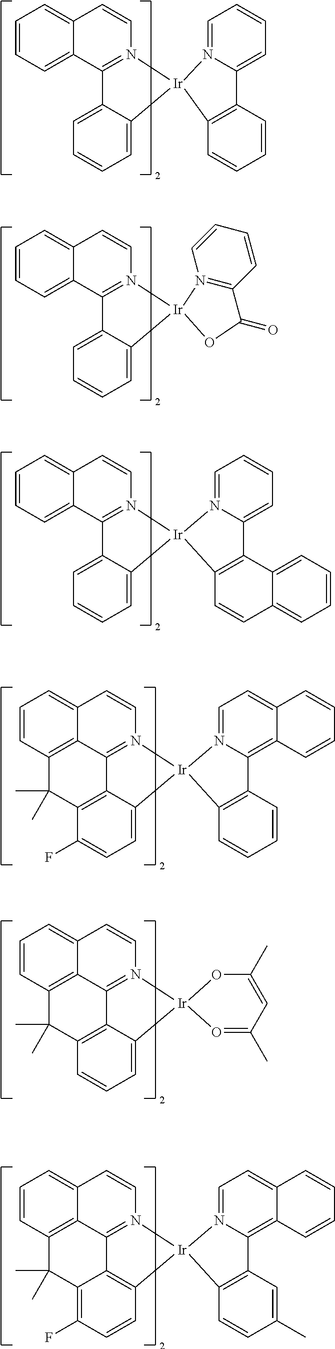

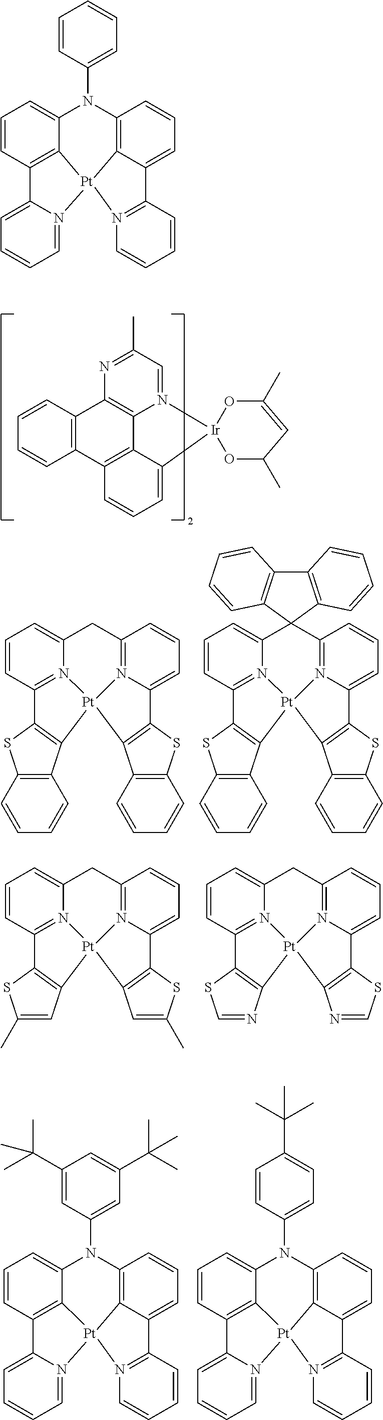

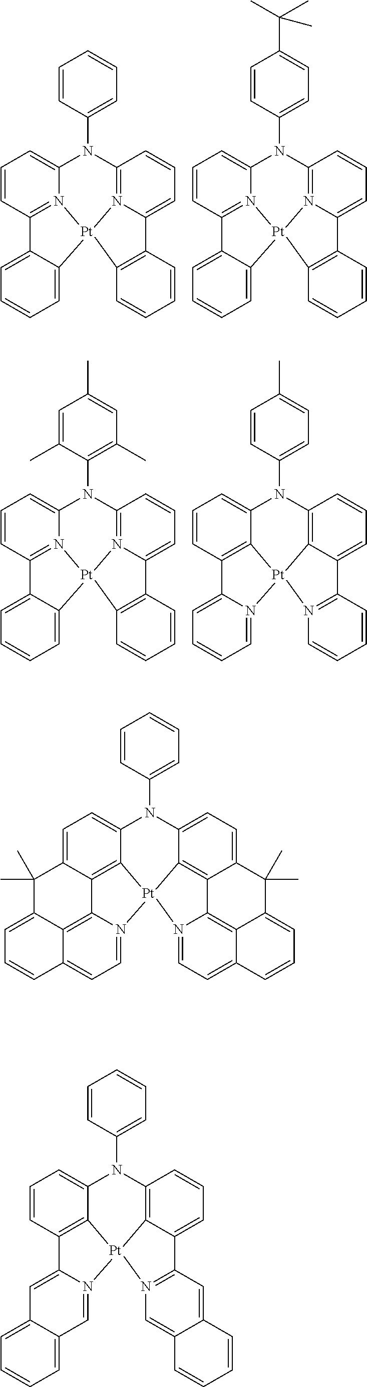

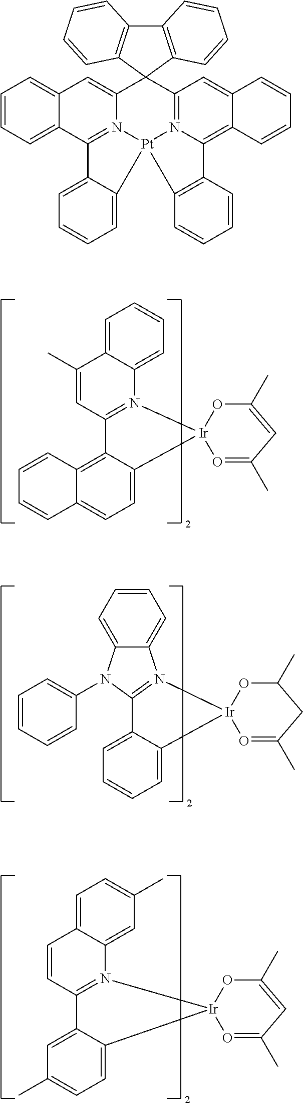

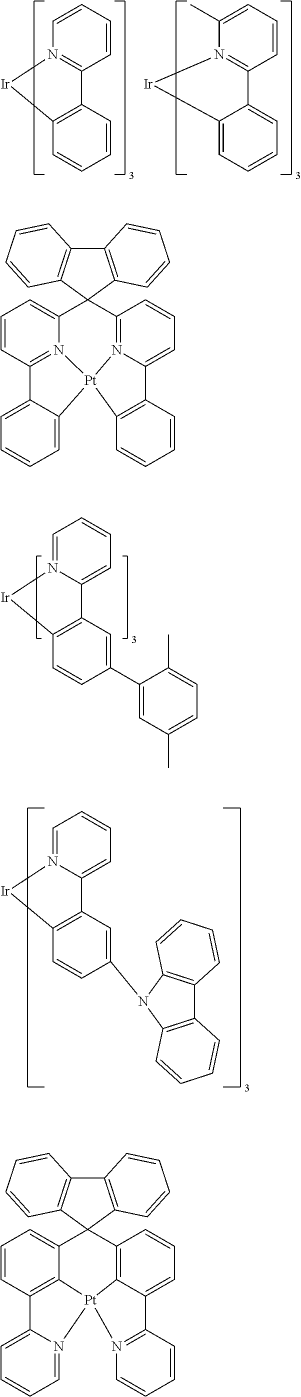

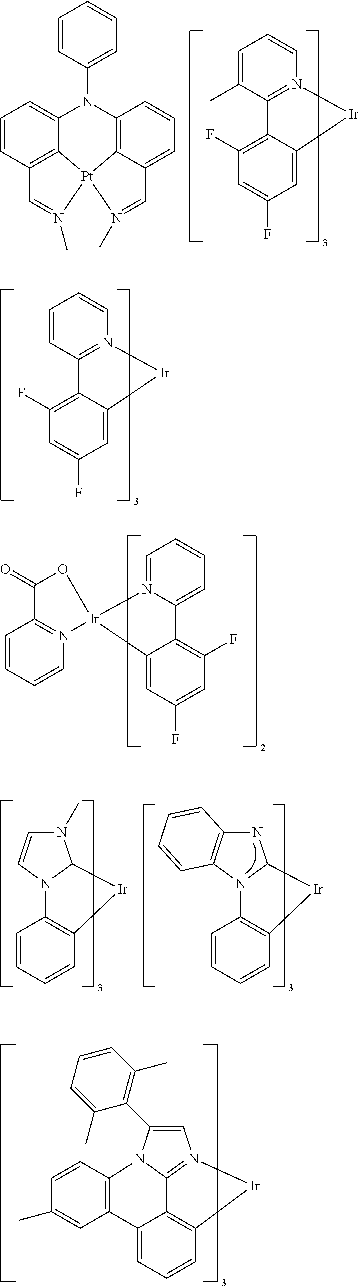

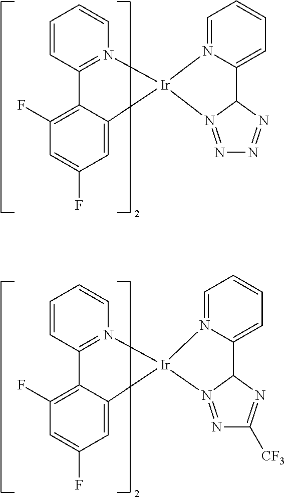

6. Polymers

In some embodiments, the organic functional materials described above, including HIM, HTM, ETM, EIM, Host, fluorescent emitter, and phosphorescent emitters, may be in the form of polymers.

In a preferred embodiment, the polymer suitable for the present disclosure is a conjugated polymer. In general, the conjugated polymer may have the general formula:

BₓA_{y} Chemical Formula 1

wherein B, A may be independently selected as the same or different structural units in multiple occurrences.

B: a π-conjugated structural unit with relatively large energy gap, also referred to as backbone unit, which may be selected from monocyclic or polycyclic aryl or heteroaryl, preferably in the form of benzene, biphenylene, naphthalene, anthracene, phenanthrene, dihydrophenanthrene, 9,10-dihydrophenanthroline, fluorene, difluorene, spirobifluorene, p-phenylenevinylene, trans-indenofluorene, cis-indenofluorene, dibenzol-indenofluorene, indenonaphthalene and derivatives thereof.

A: a π-conjugated structural unit with relatively small energy gap, also referred to as a functional unit, which, according to different functional requirements, may be selected from structural units comprising the above-mentioned hole-injection or hole-transport material (HIM/HTM), hole-blocking material (HBM), electron-injection or electron-transport material (EIM/ETM), electron-blocking material (EBM), organic host material (Host), singlet emitter (fluorescent emitter), or multiplet emitter (phosphorescent emitter).

x, y: >0, and x+y=1.

In a preferred embodiment, the polymer HTM material is a homopolymer, and the preferred homopolymer is selected from the group consisting of polythiophene, polypyrrole, polyaniline, polybenzene triarylamine, polyvinylcarbazole and their derivatives.

In another preferred embodiment, the polymer HTM material is a conjugated copolymer represented by Chemical Formula 1, wherein

A: a functional group having a hole transporting capacity, which may be selected from structural units comprising the above-mentioned hole-injection or hole-transport material (HIM/HTM); in a preferred embodiment, A is selected from the group consisting of amine, benzenesulfonates, thiophenes and thiophenes such as dithienothiophene and thiophene, pyrrole, aniline, carbazole, indolecarbazole, indeno-benzofluorene, pentacene, phthalocyanine, porphyrins and their derivatives.

x,y: >0, and x+y=1; usually y≥0.10, preferably ≥0.15, more preferably ≥0.20, preferably x=y=0.5.

Examples of suitable conjugated polymers that can be used as HTM are listed below:

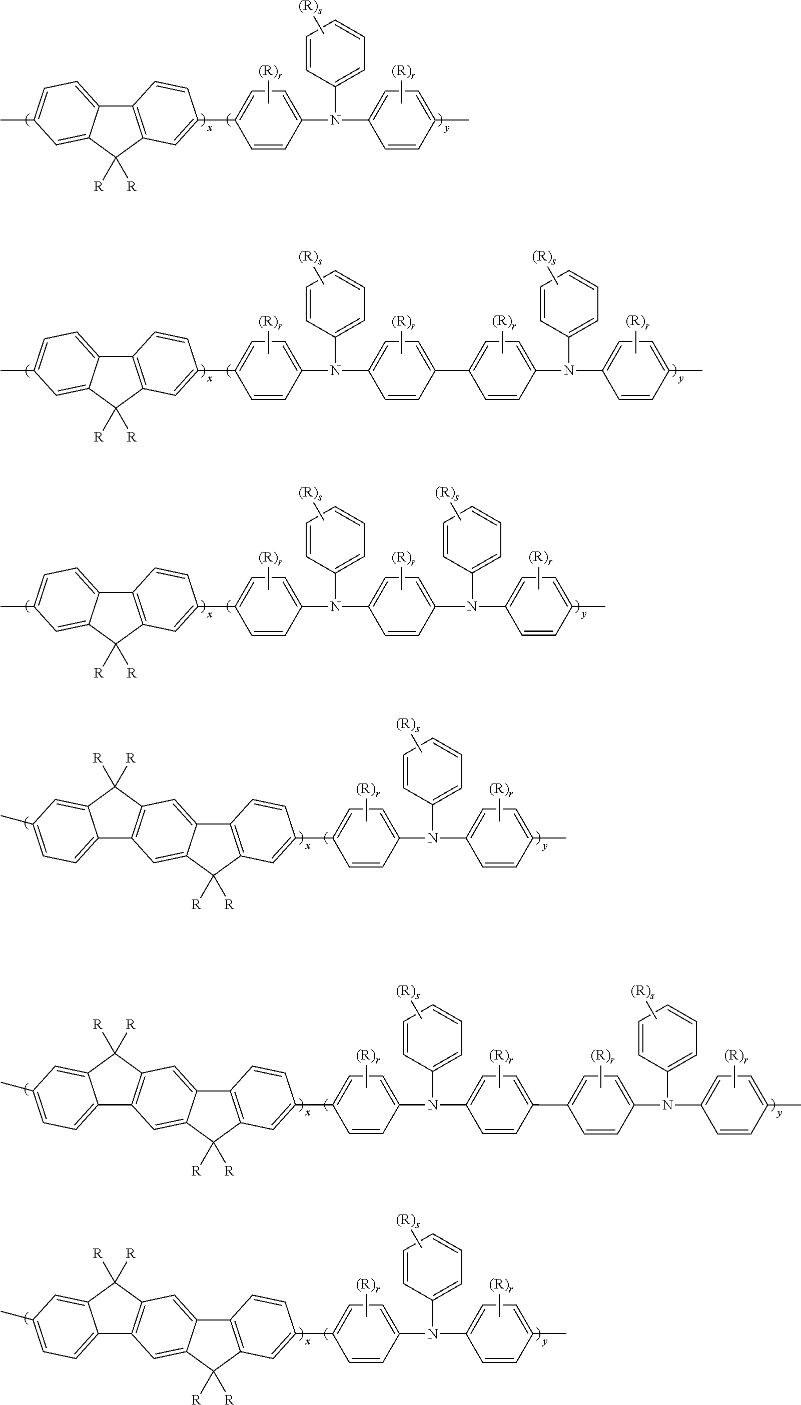

wherein R are each independently hydrogen; a straight chain alkyl group, an alkoxy group or a thioalkoxy group having 1 to 20 C atoms; a branched or cyclic alkyl group, an alkoxy group or a thioalkoxy group or a silyl group having 3 to 20 C atoms; or a substituted keto group having 1 to 20 C atoms; an alkoxycarbonyl group having 2 to 20 C atoms; aryloxycarbonyl group having 7 to 20 C atoms; a cyano group (—CN); a carbamoyl group (—C(=O)NH₂); a haloyl group (—C(=O)—X wherein X represents a halogen atom); a formyl group (—C(=O)—H); an isocyanato group; an isocyanate group; a thiocyanate group; an isothiocyanate group; a hydroxyl group; a nitro group; a CF₃ group; Cl; Br; F; a crosslinkable group; a substituted or unsubstituted aromatic or heteroaromatic ring system having 5 to 40 ring atoms; or an aryloxy or heteroaryloxy group having 5 to 40 ring atoms, or a combination of these systems in which one or more groups R may form a single ring or polycyclic aliphatic or aromatic ring system between one another and/or with a ring bonded to the group R;

r is 0, 1, 2, 3 or 4;

s is 0, 1, 2, 3, 4 or 5;

x,y: >0, and x+y=1; usually y=y≥0.10, preferably ≥0.15, more preferably ≥0.20, preferably x=y=0.5.

Another preferred type of organic ETM material is a polymer having an electron transporting capacity comprising a conjugated polymer and a nonconjugated polymer.

The preferred polymer ETM material is a homopolymer, which is selected from the group consisting of polyphenanthrene, polyphenanthroline, polyindenyl fluorene, poly spiethylene fluorene, polyfluorene and their derivatives.

The preferred polymer ETM material is a conjugated copolymer represented by Chemical Formula 1, wherein A can be independently selected in the same or different forms in multiple occurrencs:

A: a functional group having a electron transporting capacity, preferably selected from the group consisting of tris (8-quinolinolato) aluminum, benzene, biphenylene, naphthalene, anthracene, phenanthrene, dihydrophenanthrene, fluorene, difluorene, spirobifluorene, p-phenylenevinylene, pyrene, perylene, 9,10-dihydrophenanthroline, phenoxazine, phenanthroline, trans-indenofluorene, cis-indenonfluorene, dibenzol-indenofluorene, indenonaphthalene, benzanthracene and their derivatives.

x,y: >0, and x+y=1; usually y≥0.10, preferably ≥0.15, more preferably ≥0.20, preferably x=y=0.5.

In a preferred embodiment, light-emitting polymers are conjugated polymers having the following formula:

BₓA₁_{y}A₂_{z} Chemical Formula 2

B: as defined in chemical formula 1.

A1: a functional group having a hole or electron transporting capacity, which may be selected from structural units of the above-mentioned hole-injection or hole-transport material (HIM/HTM), or electron injection or transport material.

A2: a group having light emitting function, which may be selected from structural units of singlet emitter (fluorescent emitter) or multiplet emitter (phosphorescent emitter).

x,y,z: >0, and x+y+z=1;

Examples of light-emitting polymers are disclosed in the following patent applications: WO2007043495, WO2006118345, WO2006114364, WO2006062226, WO2006052457, WO2005104264, WO2005056633, WO2005033174, WO2004113412, WO2004041901 , WO2003099901, WO2003051092, WO2003020790, WO2003020790, US2020040076853, US2020040002576, US2007208567, US2005962631, EP201345477, EP2001344788 , DE102004020298, the whole contents of which are incorporated herein by reference.

In another embodiment, the polymers suitable for the present disclosure may be non-conjugated polymers. The non-conjugated polymer may be a polymer of which the backbone is non-conjugated and with all functional groups on the side chain. Examples of such non-conjugated polymers for use as phosphorescent host or phosphorescent emitter materials may be found in patent applications such as U.S. Pat. No. 7,250,226 B2, JP2007059939A, JP2007211243A2 and JP2007197574A2. Examples of such non-conjugated polymers used as fluorescent light-emitting materials may be found in the patent applications JP2005108556, JP2005285661, and JP2003338375. In addition, the non-conjugated polymer may also be a polymer, with the conjugated functional units on the backbone linked by non-conjugated linking units. Examples of such polymers are disclosed in DE102009023154.4 and DE102009023156.0. The whole contents of the above mentioned patent documents are incorporated herein by reference.

7. Colloidal Quantum Dot Light Emitting Material

In certain embodiments, the average particle size of the quantum dot light emitting material is in the range of about 1 to 1000 nm. In certain embodiments, the quantum dot light emitting material has an average particle size of about 1 to 100 nm. In certain embodiments, the quantum dot light emitting material has an average particle size of about 1 to 20 nm, preferably from 1 to 10 nm. In particular, the quantum dot light emitting material has a monodisperse particle size.

The quantum dot light emitting material comprises an inorganic semiconductor material. The semiconductors forming the luminous quantum dots may comprise one Group IV element, a group of Group II-VI compound, a group of Group II-V compound, a group of Group III-VI compound, a group of Group III-V compound, a group of Group IV-VI compound, a group of Group I-III-VI compound, a group of Group II-IV-VI compound, a group of Group II-IV-V compound, an alloy comprising any of the above classes, and/or a mixture comprising the above-mentioned compounds including ternary, quaternary mixtures or alloys. A list of non-limiting examples includes zinc oxide, zinc sulfide, zinc selenide, zinc telluride, cadmium oxide, cadmium sulfide, cadmium selenide, cadmium telluride, magnesium sulfide, magnesium selenide, gallium arsenide, gallium nitride, gallium phosphide, gallium selenide, gallium antimonide, mercuric oxide, mercuric sulfide, mercury selenide, mercury telluride, indium arsenide, indium nitride, indium phosphide, indium antimonide, aluminum arsenide, aluminum nitride , aluminum phosphide, aluminum antimonide, titanium nitride, titanium phosphate, titanium arsenide, titanium antimonide, lead oxide, lead sulfide, lead selenide, lead telluride, germanium, silicon, an alloy comprising any of the above compounds, and/or a mixture comprising any of the above compounds, including ternary, quaternary mixtures or alloys.

In a preferred embodiment, the luminous quantum dots comprise a Group II-VI semiconductor material, preferably selected from CdSe, CdS, CdTe, ZnO, ZnSe, ZnS, ZnTe, HgS, HgSe, HgTe, CdZnSe and any combination thereof. In a suitable embodiment, CdSe is used as a nano light emitting material for visible light due to the relatively mature synthesis thereof.

In another preferred embodiment, the luminous quantum dots comprise a Group III-V semiconductor material, preferably selected from InAs, InP, InN, GaN, InSb, InAsP, InGaAs, GaAs, GaP, GaSb, AlP, AlN, AlAs, AlSb , CdSeTe, ZnCdSe, and any combination thereof.

In another preferred embodiment, the luminous quantum dots comprise a Group IV-VI semiconductor material, preferably selected from PbSe, PbTe, PbS, PbSnTe, Tl2SnTe5, and any combination thereof.

Examples of the shape of the luminous quantum dots and other nanoparticles may include spherical, rod, disc, cruciform, T-shaped, other shapes, or mixtures thereof. There are several ways to make luminous quantum dots, and a preferred method is to control the growth of the solution colloid method. For more information on this method, see Alivisatos, A P, Science 1996, 271, p933; X. Peng et al., J. Am. Chem. Soc. 1997, 119, p7019; and C B Murray et al. 1993, 115, p8706. The contents of the above-listed documents are hereby incorporated by reference.

In a preferred embodiment, the luminous quantum dots comprise a core consisting of a first semiconductor material and a shell consisting of a second semiconductor material, wherein the shell is deposited at least on a portion of the core surface. A luminous quantum dot containing a core and a shell is also called a “core/shell” quantum dot.

The semiconductor material constituting the shell may be the same as or different from the core component. The shell of the “core/shell” quantum dots is a jacket wrapped on the core surface, and the material of the shell may comprise a group of Group IV elements, a group of Group II-VI compound, a group of Group II-V compound, a group of Group III-VI Compound, a group of Group III-V compounds, a group of Group IV-VI compounds, a group of Group I-III-VI compounds, a group of Group II-IV-VI compounds, a group of Group II-IV-V compounds, a alloy including any of the above-mentioned class, and/or mixtures comprising the above-mentioned compounds. Examples include, but are not limited to, ZnO, ZnS, ZnSe, ZnTe, CdO, CdSe, CdTe, MgSe, MgSe, GaAs, GaN, GaP, GaSe, GaSb, HgO, HgS, HgSe, HgTe, InAs, InN, InSb, AlAs, AlN, AlP, AlSb, TIN, TIP, TlAs, TlSb, PbO, PbS, PbSe, PbTe, Ge, Si, an alloy and/or mixture comprising any of the compounds described above.

In some embodiments, two or more shells may be induced, such as CdSe/CdS/ZnS and CdSe/ZnSe/ZnS core/shell/shell structures (J. Phys. Chem. B 2004, 108, p18826) . The intermediate shell (CdS or ZnSe) between the cadmium selenide core and zinc sulfide shell can effectively reduce the stress inside the nanocrystals, since lattice parameters of CdS and ZnSe are between that of the CdSe and ZnS, thus nanocrystals nearly without any defective can be obtained.

In certain embodiments, it is preferred that the semiconductor nanocrystals have ligands attached thereto.

The luminescence spectrum of the luminous quantum dots can be narrowly gaussian. By adjusting the size of the nanocrystalline grains, or the composition of the nanocrystals, or both, the luminescence spectrum of the luminous quantum can be continuously controlled from the entire wavelength range of the ultraviolet, visible or infrared spectrum. For example, a CdSe-containing or quantum dots can be adjusted in the visible region, and one including indium arsenide or quantum dots can be adjusted in the infrared region. The narrow particle size distribution of a luminous quantum dot leads to a narrow luminescence spectrum. The collection of grains may exhibit a monodisperse, preferably a diameter deviation of less than 15% rms, more preferably less than 10% rms, and most preferably less than 5% rms. The luminescence spectrum of the visible light luminous quantum dots is in a narrow range, and generally the full width at half maximum(FWHM) is not more than 75 nm, preferably not more than 60 nm, more preferably not more than 40 nm, and most preferably not more than 30 nm. For infrared light luminous quantum dots, the luminescence spectrum thereof may have a full width at half maximum (FWHM) of not more than 150 nm, or not more than 100 nm. The luminescence spectrum narrows with the width of the quantum dot particle size distribution.

The luminous quantum dots may have quantum luminescence efficiencies such as greater than 10%, 20%, 30%, 40%, 50%, and 60%. In a preferred embodiment, the quantum luminescence efficiency of the luminescent quantum dots is greater than 70%, more preferably greater than 80%, and most preferably greater than 90%.

Other materials, techniques, methods, applications and information useful in the present disclosure are described in the following patent documents, WO2007/117698, WO2007/120877, WO2008/108798, WO2008/105792, WO2008/111947, WO2007/092606, WO2007/Inventions in WO2008/033388, WO2008/085210, WO2008/13366, WO2008/063652, WO2008/063653, WO2007/143197, WO2008/070028, WO2008/063653, U.S. Pat. No. 6,207,229, U.S. Pat. No. 6,251,303, U.S. Pat. No. 6,319,426, U.S. Pat. No. 6,426,513, U.S. Pat. No. 6,576,291, U.S. Pat. No. 6,607,829, U.S. Pat. No. 6,861,155, U.S. Pat. No. 6,921,496 U.S. Pat. Nos. 7,606,03, 7,125,605, U.S. Pat. No. 7,138,098, U.S. Pat. No. 7,150,910, U.S. Pat. No. 7,470,379, U.S. Pat. No. 7,566,476, WO2006134599A1, the entire contents of which are hereby incorporated by reference.

In another preferred embodiment, the luminous quantum dots are nanorods. The properties of nanorods are different from spherical nanocrystals. For example, the luminescence of the nanorods is polarized along the long rod axis, while the luminescence of the spherical grains is unpolarized (see Woggon et al., Nano Lett., 2003, 3, p509). The nanorods have excellent optical gain properties, so that they may be used as laser gain materials (see Banin et al. Adv. Mater. 2002, 14, p317). In addition, the luminescence of the nanorods can be reversibly opened and closed under the control of an external electric field (see Banin et al., Nano Lett. 2005, 5, p1581). These properties of the nanorods may, in some cases, be preferably incorporated into the device of the present disclosure. Examples of preparations of semiconductor nanorods are described in WO03097904A1, US2008188063A1, US2009053522A1, KR20050121443A, the entire contents of which are hereby incorporated by reference.

8. Soluble Functional Material and a Composition Suitable for Printing.

It is a primary object of the present disclosure to prepare a functional layer, in particular a light emitting layer, in an OLED or QLED as described above by printing. A prerequisite for this purpose is that the corresponding functional material is soluble in an organic solvent.

The polymer material is easily soluble in a certain organic solvent.

The colloidal quantum dot light emitting material can be used to adjust the solubility by selecting the ligand attached to the above as described above.

Organic small molecular material can be obtained by grafting the solubilized structural unit on the organic functional material to achieve good solubility, as shown in the following general formula:

FSG]ₖ

Wherein F is an organic functional unit, SG is a solubilizing structural unit, and k is an integer from 1 to 10. By selecting SG and its number can increase the molecular weight and solubility of organic small molecular materials. In a preferred embodiment, the SG is optionally selected from structural units as shown in the following general formula, as disclosed in WO2011137922A1:

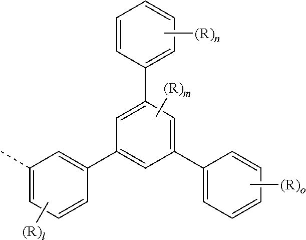

Wherein R is a substituent, l is 0, 1, 2, 3 or 4, m is 0, 1, 2 or 3 and n is 0, 1, 2, 3, 4 or 5.

In order to facilitate printing, another condition is that there must be a suitable composition comprising a functional material as described above, and at least one organic solvent.

Examples of organic solvents include, but are not limited to, methanol, ethanol, 2-methoxyethanol, dichloromethane, trichloromethane, chlorobenzene, o-dichlorobenzene, tetrahydrofuran, anisole, morpholine, toluene, o-xylene, m-xylene, p-xylene, 1,4-dioxane, acetone, methyl ethyl ketone, 1,2-dichloroethane, 3-phenoxytoluene, 1,1,1-trichloroethane, 1,1,2,2-tetrachloroethane, ethyl acetate, butyl acetate, dimethylformamide, dimethylacetamide, dimethyl sulfoxide, tetrahydronaphthalene, naphthalene alkanes, indene and/or mixtures thereof.

In a preferred embodiment, the appropriate composition is a solution.

In another preferred embodiment, the suitable composition is a suspension.

The suitable composition may comprise from 0.01 to 20% by weight of a functional functional material or a mixture thereof, preferably from 0.1 to 15% by weight, more preferably from 0.2 to 10% by weight, most preferably from 0.25 to 5% by weight of functional materials or mixtures thereof.

The solution or suspension may additionally comprise one or more components such as surface active compounds, lubricants, wetting agents, dispersing agents, hydrophobic agents, binders, etc. for adjusting viscosity, film forming properties, and improving adhesion, and the like.

The present disclosure also relates to a preparation method by printing or coating.

Among them, suitable printing or coating techniques may include, but not limited to, ink-jet printing, nozzle printing, typography, screen printing, dip coating, spin coating, blade coating, roll printing, torsion printing, lithography, flexography, rotary printing, spray coating, brush coating or pad printing, slot die coating, and so on. Preferred are gravure printing, nozzle printing and inkjet printing. For more information about printing techniques and their requirements for solutions, such as solvent, concentration, viscosity, etc., see Handbook of Print Media: Technologies and Production Methods, edited by Helmut Kipphan, ISBN 3-540-67326-1.

The display according to the disclosure comprises a substrate. The substrate may be opaque or transparent. Transparent substrates may be used to make transparent light-emitting components. See, for example, Bulovic et al., Nature 1996, 380, p29, and Gu et al., Appl. Phys. Lett. 1996, 68, p2606. The substrate may be rigid or flexible. The substrate may be plastic, metal, semiconductor wafer or glass. Most preferably the substrate has a smooth surface. Substrates free of surface defects are particularly desirable. In a preferred embodiment, the substrate is flexible and may be selected from polymer films or plastic, with a glass transition temperature (Tg) of 150° C. or above, more preferably above 200° C., more preferably above 250° C., and most preferably above 300° C. Examples of suitable flexible substrates are poly (ethylene terephthalate) (PET) and polyethylene glycol (2,6-naphthalene) (PEN).

The display device according to the disclosure is characterized in that each sub-pixel comprises at least one thin film transistor (TFT). In a preferred embodiment, the TFTs may be selected from the group consisting of LTPS-TFTs, HTPS-TFTs, a-Si-TFTs, metal oxide TFTs, organic transistors (OFET) and carbon nanotube transistors (CNT-FETs).

The anode may comprise a conductive metal or a metal oxide, or a conductive polymer. The anode may easily inject holes into the hole-injection layer (HIL) or the hole-transport layer (HTL) or the light-emitting layer. In one embodiment, the absolute value of the difference between the work function of the anode and the HOMO energy level or the valence band energy level of the emitter in the light-emitting layer or of the p-type semiconductor material of the HIL or HTL or the electron-blocking layer (EBL) may be smaller than 0.5 eV, more preferably smaller than 0.3 eV, and most preferably smaller than 0.2 eV. Examples of anode materials may include, but not limited to, Al, Cu, Au, Ag, Mg, Fe, Co, Ni, Mn, Pd, Pt, ITO, aluminum-doped zinc oxide (AZO), and the like. Other suitable anode materials are known and may be readily selected for use by a person skilled in the art. The anode material may be deposited using any suitable technique, such as suitable physical vapor deposition, including RF magnetron sputtering, vacuum thermal evaporation, electron beam (e-beam), and the like. In some embodiments, the anode may be patterned.

The cathode may comprise a conductive metal or a metal oxide. The cathode may easily inject electrons into the EIL or ETL or directly into the light-emitting layer. In one embodiment, the absolute value of the difference between the work function of the cathode and the LIJMO energy level or the valence band energy level of the emitter in the light-emitting layer or of the n-type semiconductor material of the electron-injection layer (EIL) or the electron-transport layer (ETL) or the hole-blocking layer (HBL) may be smaller than 0.5 eV, more preferably smaller than 0.3 eV, and most preferably smaller than 0.2 eV In principle, all of the material that may be used as the cathode of an OLED may serve as a cathode material for the device of the present disclosure. Examples of the cathode material may include, but not limited to, Al, Au, Ag, Ca, Ba, Mg, LiF/Al, MgAg alloys, BaF2/Al, Cu, Fe, Co, Ni, Mn, Pd, Pt, ITO, and the like. The cathode material may be deposited using any suitable technique, such as suitable physical vapor deposition, including RF magnetron sputtering, vacuum thermal evaporation, electron beam (e-beam), and the like.

OLED or QLED can also contain other functional layers such as hole injection layer (HIL), hole transport layer (HTL), electron blocking layer (EBL), electron injection layer (EIL), electron transport layer (ETL) and hole-blocking layer (HBL). These functional layers can be formed by printing or physical vapor deposition.

The printing of the multilayer film can be achieved by selecting an orthogonal solvent, or by using an organic compound which is crosslinked by light or heat.

In a preferred embodiment, in the display device of the present disclosure, the light emitting layer of the green sub-pixel is prepared by ink jet printing, nozzle printing or gravure printing.

In a preferred embodiment, in the display device according to the present disclosure, either or both of the light-emitting layers of the red and blue sub-pixels contain colloidal quantum dot light emitting material, wherein the light emitting layer of the quantum dots is prepared by ink jet printing, nano imprinting or concave printing.

A combination of sub-pixels suitable for the present disclosure is shown below, in which the light-emitting layer is printed:

| | Light emitting | Light emitting | Light emitting |
|---|---|---|---|
| | material of the | material of the | material of the |
| | red sub-pixels | green sub-pixels | blue sub-pixels |
| Scheme 1 | Quantum dots | Small molecules | Polymers |
| Scheme 2 | Quantum dots | Small molecules | Quantum dots |
| Scheme 3 | Polymers | Small molecules | Quantum dots |
| Scheme 4 | Quantum dots | Small molecules | Small molecules |
| Scheme 5 | Small molecules | Small molecules | Quantum dots |
| Scheme 6 | Quantum dots | Polymers | Polymers |
| Scheme 7 | Quantum dots | Polymers | Quantum dots |
| Scheme 8 | Polymers | Polymers | Quantum dots |
| Scheme 9 | Quantum dots | Polymers | Small molecules |
| Scheme 10 | Small molecules | Polymers | Quantum dots |

In a preferred embodiment, in the display device according to the present disclosure, the red, green, and blue sub-pixels each includes a hole injection layer and/or a hole transport layer.

In a particularly preferred embodiment, the red, green, and blue sub-pixels each includes an identical hole injection layer and/or an identical hole transport layer, wherein the hole injection layer and/or the hole transport layer is prepared by printing, and the printing method may be selected from ink-jet printing, screen printing, gravure printing, spray printing, and slot-die coating.

In a preferred embodiment, in the display device according to the present disclosure, the red, green, and blue sub-pixels each includes an identical hole injection layer selected from the group consisting of NiOx, WOx, MoOx, RuOx, VOx and any combination thereof, or conductive polymer.

In a preferred embodiment, in the display device according to the present disclosure, the red and green blue sub-pixels each includes an electron injection layer and/or an electron transport layer.

In a particularly preferred embodiment, the red, green, and blue sub-pixels each includes an identical electron injection layer and/or an identical electron transport layer, wherein both the electron injection layer and/or the electron transport layer are formed by physical gas deposition method, such as vacuum heat evaporation.

The present disclosure also provides a method for preparing a display device comprising the steps of:

1) depositing a patterned anode on the substrate

2) depositing a hole injection layer on the anode

3) depositing a hole transport layer on the hole injection layer

4) preparing red, green and blue colored light emitting layers on the hole transport layer by printing

5) depositing an electron transport layer on the light emitting layer

Wherein the printing method is as described above, preferably gravure printing, nozzle printing or ink jet printing.

In a preferred embodiment, the method of preparation is characterized in that the depositing in the steps 2) and 3) is achieved by printing.

The disclosure will now be described in combination with the preferred embodiments, but the disclosure is not to be limited to the following examples. It is to be understood that the appended claims summarize the scope of the disclosure. It is to be understood that certain changes to the various embodiments of the disclosure will be covered by the spirit and scope of the claims of the disclosure.

### EXAMPLES

Preparation of QLED

Red QLED1 material, device structure with reference to Nature vol515 96 (2014), each layer can be printed by inkjet.

Preparation of OLED devices:

Green light emitting polymer Poly (9,9-di-n-octylfluorenyl-2,7-diyl)-alt-(benzo [2,1,3]thiadiazol-4,8-diyl]] (F8BT), 698687 Aldrich , was used as a polymer emitter.

Blue light-emitting polymer P1(see WO2008011953A1) was used as a polymer emitter.

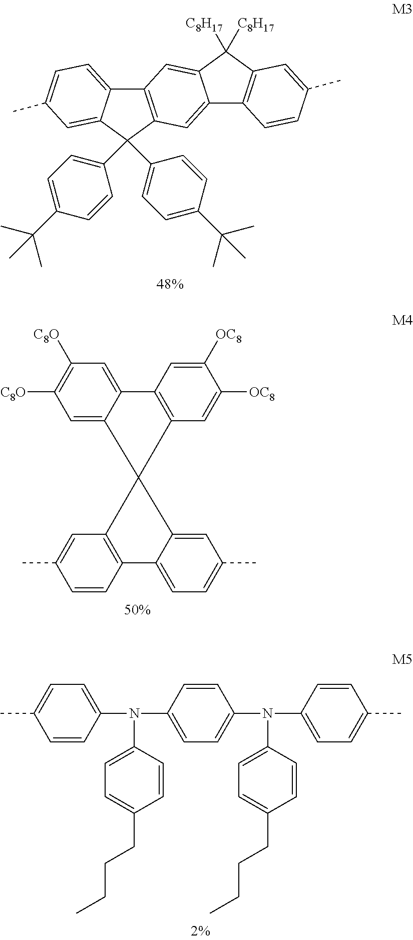

H1 and H2 described below were the host materials of the soluble small molecule OLED, and G1 was the light emitting material of the soluble small molecule OLED, and its synthesis is described in WO2011137922A1.

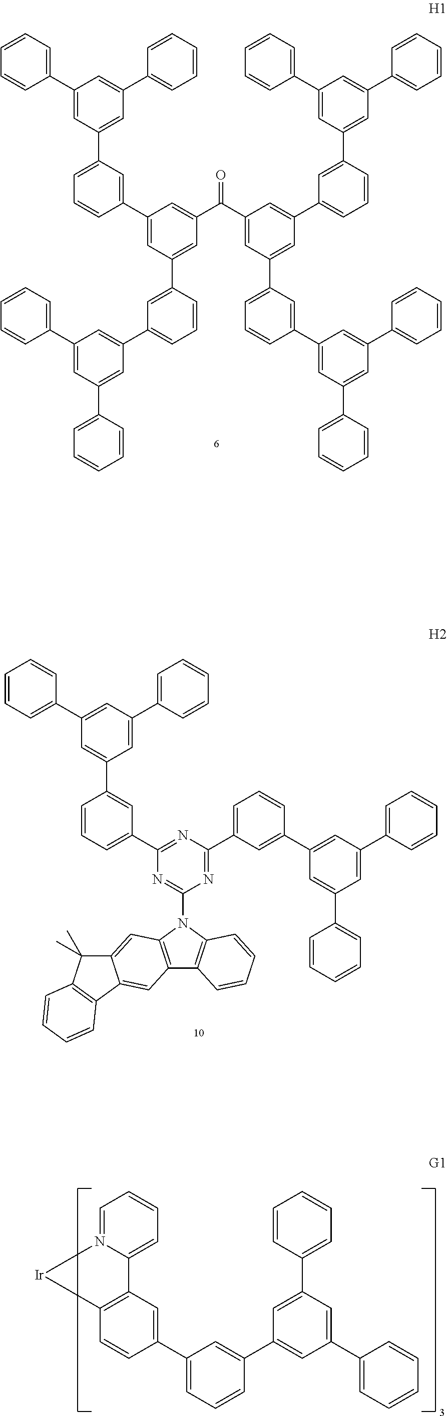

TFB (H. W. SandsCorp.) was as a hole transport material, the structure of which is shown below.

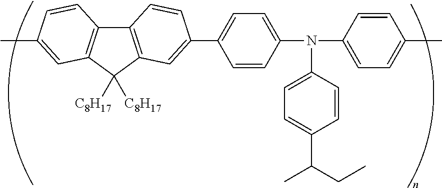

The OLED can be prepared as follows:

1) An ITO conductive glass substrate was cleaned using a variety of solvents (chloroform→acetone→isopropyl alcohol) for the first time, and then was treated with UV ozone plasma.

2) HIL: PEDOT: PSS (Clevios P VP AI4083) was coated on the ITO conductive glass substrate in a clean room with a slot-die coating in the air to obtain a thickness of 80 nm, and then was baked in air at 120° C. for 10 minutes to remove moisture.

3) HTL: TFB (H W SandsCorp.) was used as the hole transport layer, and was dissolved in mesitylene at a concentration of 5 wt %. The solution was sprayed on a PEDOT: PSS film by ink jet printing in a nitrogen glove box, and then was annealed at 180° C. for 60 minutes, to obtain TFB with a thickness of 10-20 nm.

4) EML: The light-emitting layer is formed by ink-jet printing, and the corresponding solution and thickness are shown in the following table

| | EML composition | Solvent and its | Thick- | |
|---|---|---|---|---|
| Device | (wt %) | concentration | ness | Color |
| OLED1 | F8BT(100) | Mesitylene, 0.7 wt % | 80 nm | green |
| OLED2 | P1(100) | Mesitylene, 0.6 wt % | 65 nm | blue |
| OLED3 | H1(40):H2(40):G1(20) | 3-phenoxytoluene, | 80 nm | green |
| | | 2.5 wt % | | |

5) Cathode: LiF/Al (1 nm/150 nm) was thermally vaporized in high vacuum (1×10⁻⁶ mbar) 6) Package: The device was encapsulated with a UV hardening resin in an ultraviolet glove box.

In this way, a tri-color printed display having the following combination can be obtained:

| | Red sub-pixels | Green sub-pixels | Blue sub-pixels |
|---|---|---|---|
| Display device 1 | QLED1 | OLED1 | OLED2 |
| Display device 2 | QLED1 | OLED3 | OLED2 |

It is to be understood that the application of the disclosure is not limited to the above-described examples, and that a person skilled in the art may make modification or amendments in accordance with the above description, all of which are within the scope of the claims appended hereto.

1-14. (canceled)

15. A display device comprising red, green and blue sub-pixels, wherein each sub-pixel is an electroluminescent device and includes a light-emitting layer, wherein:
1) the light-emitting layer of the green sub-pixel contains organic light-emitting material,
2) either or both of the light-emitting layers of the red and blue sub-pixels contain colloidal quantum dot light-emitting material, and
3) the light-emitting layers of the red, green and blue sub-pixels are all prepared by printing.

16. The display device of claim 15, wherein the light emitting layer of the green sub-pixel is prepared by inkjet printing, nozzle printing or gravure printing.

17. The display device of claim 15, wherein either or both of the light-emitting layers of the red and blue sub-pixels comprise colloidal quantum dot light-emitting material, wherein the light emitting layer containing the quantum dots is prepared by ink jet printing, nano imprinting, or gravure printing.

18. The display device of claim 15, wherein the red, green and blue sub-pixels each comprises a hole injection layer and/or a hole transport layer.

19. The display device of claim 18, wherein the red, green and blue sub-pixels each comprises an identical hole injection layer and/or an identical hole transport layer, wherein the hole injection layer and/or the hole transport layer is prepared by printing, and the printing method is selected from ink-jet printing, screen printing, gravure printing, spray printing, and slot-die coating.

20. The display device of claim 18, wherein the red, green and blue sub-pixels each includes an identical hole-injecting layer comprising a material selected from the group consisting of NiOx, WOx, MoOx, RuOx, VOx and any combination thereof, or a conductive polymer.

21. The display device of claim 15, wherein the red, green and blue sub-pixels each comprises_an electron injection layer and/or an electron transport layer.

22. The display device of claim 15, wherein the organic light-emitting material is selected from the group consisting of organic small molecules, polymers and organic metal complexes.

23. The display device of claim 15, wherein the colloidal quantum dot light-emitting material comprises i semiconductor material selected from the group consisting of CdSe, Cds, CdTe, ZnO, ZnSe, ZnS, ZnTe, HgS, HgSe, HgTe, CdZnSe, InAs, InP, InN, GaN, InSb, InAsP, InGaAs, GaAs, GaP, GaSb, AlP, AlN, AlAs, AlSb, CdSeTe, ZnCdSe, PbSe, PbTe, PbS, PbSnTe, Tl₂SnTe₅, and any combination thereof.

24. The display device of claim 15, wherein the colloidal quantum dot light-etnitting material has a heterostructure comprising two different semiconductors, wherein the heterostructure is a core/shell structure having at least one shell.

25. The display device of claim 15, wherein each sub-pixel comprises at least one thin film transistor (TFT).

26. The display device of claim 25, wherein the TFT is selected from the group consisting of LTPS-TFT, HTPS-TFT, a-Si-TFT, metal oxide TFT, organic transistor (OFET), and carbon nanotube transistor (CNT FET).

27. A method for preparing a display device; comprising the following operations:
1) depositing a patterned anode on a substrate;
2) depositing a hole injection layer on the anode;
3) depositing a hole transport layer on the hole injection layer;
4) preparing red, green and blue light emitting layers on hole transport layer of the subpixel by printing; and
5) depositing an electron transport layer on the light emitting layer.

28. The method of claim 27, wherein the deposition in each of operations 2) and 3) is achieved by printing.
